(19) United States
(12) Patent Application Publication
(10) Pub. No.: US 2015/0333117 A1
(43) Pub. Date: Nov. 19, 2015

(54) SEMICONDUCTOR DEVICE AND MANUFACTURING METHOD THEREOF

(71) Applicants: Nobuyuki Sako, Tokyo (JP); Eiji Hasunuma, Tokyo (JP); Keisuke Otsuka, Tokyo (JP)

(72) Inventors: Nobuyuki Sako, Tokyo (JP); Eiji Hasunuma, Tokyo (JP); Keisuke Otsuka, Tokyo (JP)

(21) Appl. No.: 14/651,633

(22) PCT Filed: Dec. 10, 2013
(86) PCT No.: PCT/JP2013/083099

§ 371 Date: Jun. 11, 2015

(30) Foreign Application Priority Data
Dec. 12, 2012 (JP) 2012-271555

(51) Int. Cl. H01L 49/02; H01L 27/108; H01L 21/311

(52) U.S. Cl. CPC H01L 28/90; H01L 21/31116; H01L 27/10805; H01L 21/31144

(57) ABSTRACT

One semiconductor device includes lower electrodes arranged in rows along first and second directions parallel to the surface of a semiconductor substrate and extending in a third direction perpendicular to the surface of the substrate, a first support film arranged on the upper end of the lower electrodes and having first openings, a second support film arranged in the middle of the lower electrodes in the third direction, and having second openings aligned in a plane in the same pattern as the first openings, a capacitance insulating film covering the surface of the lower electrodes, and upper electrodes covering the surface of the capacitance insulating film. A portion of each of eight lower electrodes contained in two lower electrode unit groups adjacent in the first direction are collectively positioned inside of the first and second openings. A lower electrode unit group is four lower electrodes adjacent in the second direction.

### TECHNICAL FIELD

The present invention relates to a semiconductor device and a method for producing same, and in particular the present invention relates to a semiconductor device having a structure in which lower electrodes of a crown-shaped capacitor are supported by a plurality of support films, and a method for producing same.

### BACKGROUND

Associated semiconductor devices have a plurality of insulating beams, and the method of production thereof involves forming the plurality of insulating beams in succession from the lower layer side (see Patent Document 1, for example).

To be more specific, a first insulating beam film is formed on a first sacrificial insulating film, and the first insulating beam film is selectively etched in order to form a first insulator beam having the required pattern. Next, a second sacrificial insulating film and a second insulating beam film are formed in succession on the first insulator beam and the exposed first sacrificial insulating film. The second insulating beam film is then selectively etched in the same way as with the first insulating beam film in order to form a second insulator beam having the required pattern.

After this, a through-hole is formed running through the second insulator beam, second sacrificial insulating film, first insulator beam and first sacrificial insulating film, and a conductive film constituting a lower electrode of a capacitor is formed in such a way as to cover the inner surface of the through-hole. The conductive film formed is connected to the first insulator beam and the second insulator beam exposed within the through-hole.

After this, the lower electrode is supported by means of the second insulator beam and the first insulator beam even when the second sacrificial insulating film and the first sacrificial insulating film are removed. As a result, the lower electrode is prevented from collapsing etc. and it is possible to form a crown-shaped capacitor having a higher aspect ratio.

### PATENT DOCUMENTS

Patent Document 1: JP 2003-142605 A

### SUMMARY OF THE INVENTION

### Problem to be Solved by the Invention

According to an associated method for producing a semiconductor device, a plurality of insulator beams are formed one at a time from the lower layer side, after which a through-hole is formed. There is a problem in this case in that the lower electrode formed inside the through-hole is not connected to some or all of the plurality of insulator beams if there is an offset between the pattern position of the plurality of insulator beams and the formation position of the through-hole.

Furthermore, the mechanical strength of the lower electrode itself is reduced when the film thickness of the lower electrode has to be thinned due to miniaturization of the semiconductor device, even if the plurality of lower electrodes are all connected to the insulator beams, and the lower electrodes twist because of the stress of the insulator beams and short-circuiting occurs between adjacent lower electrodes.

There is a further problem in that coverage defects become very apparent in the lower electrode if the diameter of the actual through-hole is reduced because of miniaturization of the semiconductor device, so the through-hole assumes a closed state because of the lower electrode itself which is formed in the opening of the through-hole, it is no longer possible to form a capacitance insulating film or an upper electrode inside the through-hole, and the capacitor cannot be constructed.

The present invention is intended to provide a semiconductor device which avoids the abovementioned problems, and a method for producing same.

### Means for Solving the Problem

A semiconductor device according to a first mode of embodiment of the present invention comprises: a plurality of lower electrodes which are arranged on a semiconductor substrate in a first direction parallel to the surface of the semiconductor substrate and a second direction perpendicular to the first direction, and extend in a third direction perpendicular to the surface of the semiconductor substrate; a first support film which is provided at a position corresponding to the upper end of the plurality of lower electrodes and has a plurality of first openings; a second support film which is provided at a position corresponding to the middle of the plurality of lower electrodes in relation to the third direction and has a plurality of second openings; a capacitance insulating film which covers the surface of the plurality of lower electrodes; and an upper electrode which covers the surface of the capacitance insulating film, the plurality of first openings and the plurality of second openings are aligned on a plane in the same pattern and are provided at overlapping positions in the third direction, and the plurality of first openings and the plurality of second openings are constructed in such a way that a portion of each of eight lower electrodes included in two lower electrode unit groups adjacent in the first direction are positioned together inside the respective first openings and second openings, where four lower electrodes adjacent in the second direction from among the plurality of lower electrodes constitute a lower electrode unit group.

The semiconductor device according to another aspect of the present invention comprises: a plurality of lower electrodes extending in a third direction perpendicular to a semiconductor substrate surface; a first support film which is disposed at a position corresponding to the upper ends of the plurality of lower electrodes and has a rectangular first opening; a second support film which is disposed at a position corresponding to the middle of the plurality of lower electrodes in the third direction and has a rectangular second opening; a capacitance insulating film which covers the surface of the plurality of lower electrodes; and an upper electrode which covers the surface of the capacitance insulating film, the plurality of lower electrodes, the capacitance insulating film and the upper electrode form a capacitor group, the capacitor group comprises: a first capacitor which is arranged on the sides of the first openings in plan view with part of the outer circumferential side surface of the lower electrodes being connected to the first support film; and a second capacitor in which the whole of the outer circumferential side surface of the lower electrodes is connected to the first support film without being exposed within the first opening, and the upper surfaces of the lower electrodes forming part of the first capacitor include a first upper surface which is flush with the upper surface of the first support film, and a second upper surface which is lower than the first upper surface.

The semiconductor device according to a further aspect of the present invention comprises: lower electrodes which are connected to the upper surface of a contact plug disposed on a semiconductor substrate and extend in a third direction perpendicular to the semiconductor substrate surface; a first support film which is connected to the outer circumference at the upper end of the lower electrodes; a second support film which is connected to the outer circumference of the middle section of the lower electrodes in the third direction; a capacitance insulating film which covers the surface of the lower electrodes; and an upper electrode which covers the surface of the capacitance insulating film, the lower electrodes, capacitance insulating film and upper electrode form a capacitor, the capacitor includes a lower capacitor which is positioned between the upper surface of the contact plug and the second support film, and an upper capacitor which is positioned between the lower surface of the second support film and the upper surface of the first support film, and if T1a is the film thickness of the lower electrodes of the upper capacitor at a position in proximity to the first support film, T2a is the film thickness of the lower electrodes of the upper capacitor at a position in proximity to the second support film, T3 is the film thickness of the lower electrodes of the lower capacitor at a position in proximity to the second support film, and T4 is the film thickness of the lower electrodes of the lower capacitor at a position in proximity to the contact plug, then T2a is the smallest.

The method for producing a semiconductor device according to a mode of embodiment of the present invention comprises the following steps: a step in which a stopper silicon nitride film, a first sacrificial film, a first insulating film, a second sacrificial film, and a second insulating film are formed in succession on a semiconductor substrate; a step in which a cylinder hole is formed through the second insulating film, second sacrificial film, first insulating film, first sacrificial film, and stopper silicon nitride film; a step in which the cylinder hole is widened; a step in which a lower electrode material film is formed over the whole surface of the cylinder hole including the inner surface; a step in which a protective film is formed on the upper surface of the lower electrode material film; a step in which a first opening pattern which at least partially maintains the connection between the lower electrode material film and the surface of the second insulating film forming part of the inner surface of the cylinder hole is formed on the protective film; a step in which a first support film is formed by forming a first opening in the second insulating film using the protective film as a mask; a step in which the second sacrificial film is removed through the first opening; a step in which a second opening comprising the same pattern as the first opening is formed in the first insulating film by means of anisotropic dry etching using the first support film as a mask in order to form a second support film, and the lower electrode material film formed on the upper surface of the first support film is removed to form lower electrodes in which the outer circumferential side surface is connected to the second support film and the first support film within the cylinder hole; and a step in which the whole of the first sacrificial film is removed through the second opening, the step in which the second opening is formed including a step in which the upper surface of the first support film and the upper surface of the lower electrodes is excavated while at the same time the upper side surface of the lower electrodes is degraded.

### Advantage of the Invention

According to the present invention, an opening pattern is formed in such a way that two adjacent lower electrode unit groups aligned in a first direction, from among a plurality of lower electrodes arrayed in a first direction parallel to a semiconductor substrate surface and a second direction perpendicular to the first direction, are exposed together, taking four lower electrodes adjacent in the second direction as a lower electrode unit group, and therefore twisting of the lower electrodes is avoided by alleviating stress in the actual support film, and it is possible to prevent the problem of short-circuiting between adjacent lower electrodes.

Furthermore, the side surfaces and upper surfaces of the lower electrodes of an upper capacitor are degraded in such a way that the film thickness of the lower electrodes of the upper capacitor positioned on a first support film is at its smallest at a position in proximity to the first support film, so it is possible to form a capacitor in which the diameter of the openings in the lower electrodes can be increased and closure can be avoided.

### BRIEF DESCRIPTION OF THE FIGURES

FIG. 1A is a view in cross section to illustrate the main constituent elements of a semiconductor device according to a first mode of embodiment of the present invention;

FIG. 1B is a plan view to illustrate the layout of the semiconductor device according to the first mode of embodiment of the present invention;

FIG. 1C is an enlargement in cross section of a region MC shown in the cross section of FIG. 1A;

FIG. 1D is an enlargement in cross section of the region MD shown in the cross section of FIG. 1A;

FIG. 1E is an enlargement in cross section of a capacitor C2 shown in the cross section of FIG. 1A;

FIG. 1F is an enlargement in cross section of a capacitor F2 shown in the cross section of FIG. 1A;

FIG. 2A is a view in cross section of an intermediate step along the line A-A′ shown in FIG. 2B, in order to illustrate the method for producing a semiconductor device according to the first mode of embodiment of the present invention shown in FIG. 1;

FIG. 2B is a plan view corresponding to the cross section of FIG. 2A;

FIG. 3A is a view in cross section at a position corresponding to the line A-A′ in FIG. 2B, in order to illustrate the steps following FIG. 2A;

FIG. 4A is a view in cross section at a position corresponding to the line A-A′ in FIG. 2B, in order to illustrate the step following FIG. 3A;

FIG. 4D is an enlargement of a region MD in FIG. 4A;

FIG. 5A is a view in cross section along the line A-A′ in FIG. 5B, in order to illustrate the step following FIG. 4A;

FIG. 5B is a plan view corresponding to the cross section of FIG. 4A;

FIG. 5C is an enlargement of the region MC in FIG. 5A;

FIG. 5D is an enlargement of the region MD in FIG. 5A;

FIG. 6A is a view in cross section at a position corresponding to the line A-A′ in FIG. 5B, in order to illustrate the step following FIG. 5A;

FIG. 6C is an enlargement of the region MC in FIG. 6A;

FIG. 7A is a view in cross section along the line A-A′ in FIG. 7B, in order to illustrate the step following FIG. 6A;

FIG. 7B is a plan view corresponding to the cross section of FIG. 7A;

FIG. 7C is an enlargement of the region MC in FIG. 7A;

FIG. 8A is a view in cross section at a position corresponding to the line A-A′ in FIG. 7B, in order to illustrate the step following FIG. 7A;

FIG. 8C is an enlargement of the region MC in FIG. 8A;

FIG. 9A is a view in cross section at a position corresponding to the line A-A′ in FIG. 7B, in order to illustrate the step following FIG. 8A;

FIG. 9C is an enlargement of the region MC in FIG. 9A;

FIG. 9D is an enlargement of the region MD in FIG. 9A;

FIG. 10A is a view in cross section of the position corresponding to the line A-A′ in FIG. 7B, in order to illustrate the step following FIG. 9A;

FIG. 11 is a view in cross section of a step in order to illustrate an experimental example investigated by the inventors;

FIG. 12 is a view in cross section to illustrate the step following FIG. 11;

FIG. 13 is a view in cross section to illustrate the step following FIG. 12;

FIG. 14 is a view in cross section to illustrate the step following FIG. 13;

FIG. 15 is a view in cross section to illustrate the step following FIG. 14;

FIG. 15D is an enlargement of the region MD shown in FIG. 15;

FIG. 16 is a view in cross section to illustrate the step following FIG. 15;

FIG. 17 is a view in cross section to illustrate the step following FIG. 16;

FIG. 18 is a view in cross section to illustrate the step following FIG. 17;

FIG. 19 is a view in cross section to illustrate the step following FIG. 18;

FIG. 19D is an enlargement of the region MD shown in FIG. 19;

FIG. 20 is a view in cross section to illustrate the step following FIG. 19;

FIG. 21 is a view in cross section to illustrate the step following FIG. 20;

FIG. 22 is a view in cross section to illustrate the step following FIG. 21; and

FIG. 23 is an enlargement of the region MD shown in FIG. 21.

### MODE OF EMBODIMENT OF THE INVENTION

A mode of embodiment of the present invention will be described in detail below with reference to the figures.

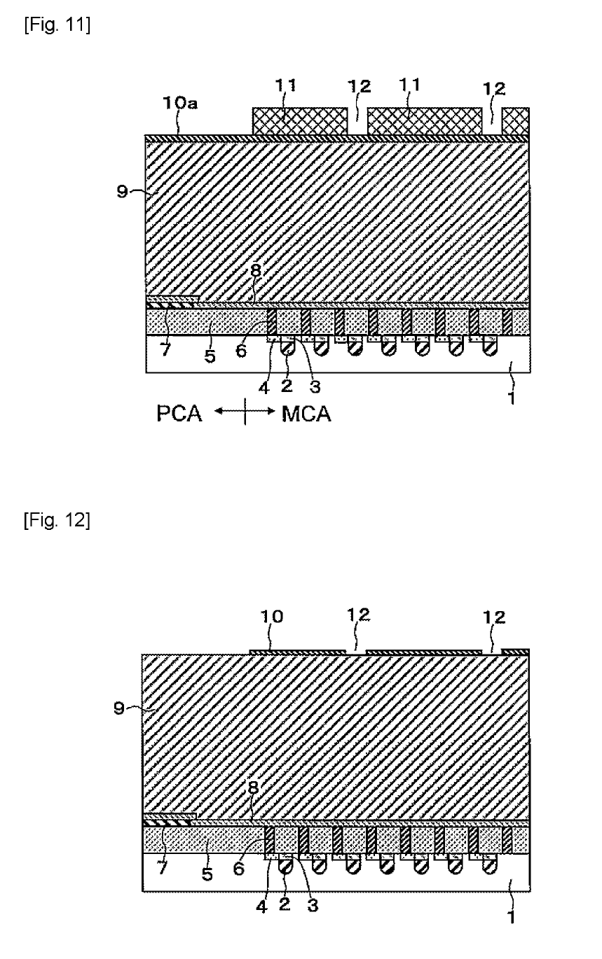

An experimental example relating to a method for producing a capacitor implemented by the inventors will be described first of all with reference to FIG. 11-23 in order to facilitate an understanding of the present invention.

### Experimental Example

FIG. 11 shows an intermediate step in the method for producing a semiconductor device which constitutes an a DRAM (Dynamic Random Access Memory). A DRAM has a peripheral circuit area PCA and a memory cell area MCA in which a plurality of capacitors are formed.

A plurality of embedded gate electrodes 2 and a cap insulating film 3 which covers the upper surfaces of the embedded gate electrodes 2 are formed on the surface of a semiconductor substrate 1 in the memory cell area MCA. An impurity diffusion layer (referred to below as a “diffusion layer”) 4 forming the source or drain is formed on the semiconductor substrate 1 adjacent to the cap insulating film 3. A plurality of (capacitance) contact plugs 6 which pass through a first interlayer insulating film 5 formed on the semiconductor substrate 1 and are contiguous with the diffusion layer 4 are formed. A bit line which is not depicted is formed within the first interlayer insulating film 5. A peripheral circuit 7 is formed on the first interlayer insulating film 5 in the peripheral circuit area PCA. A (stopper) silicon nitride film 8 is formed in such a way as to cover the first interlayer insulating film 5, contact plugs 6 and peripheral circuit 7. A first sacrificial film 9 and a first insulating film 10a are formed on the silicon nitride film 8. A first mask film 11 having a pattern comprising second openings 12 is formed on the first insulating film 10a by means of a first lithography step.

Next, as shown in FIG. 12, the first insulating film 10a is etched using the first mask film 11 as a mask, and a second support film 10 including the second openings 12 is formed.

Next, as shown in FIG. 13, a second sacrificial film 13, a second insulating film 14a, a first hard mask film 15, a second hard mask film 16 and an antireflection film 17 are formed in such a way as to cover the second support film 10 and the first sacrificial film 9. A second mask film 18 having a cylinder hole pattern 19 is formed on the antireflection film 17 by means of a second lithography step.

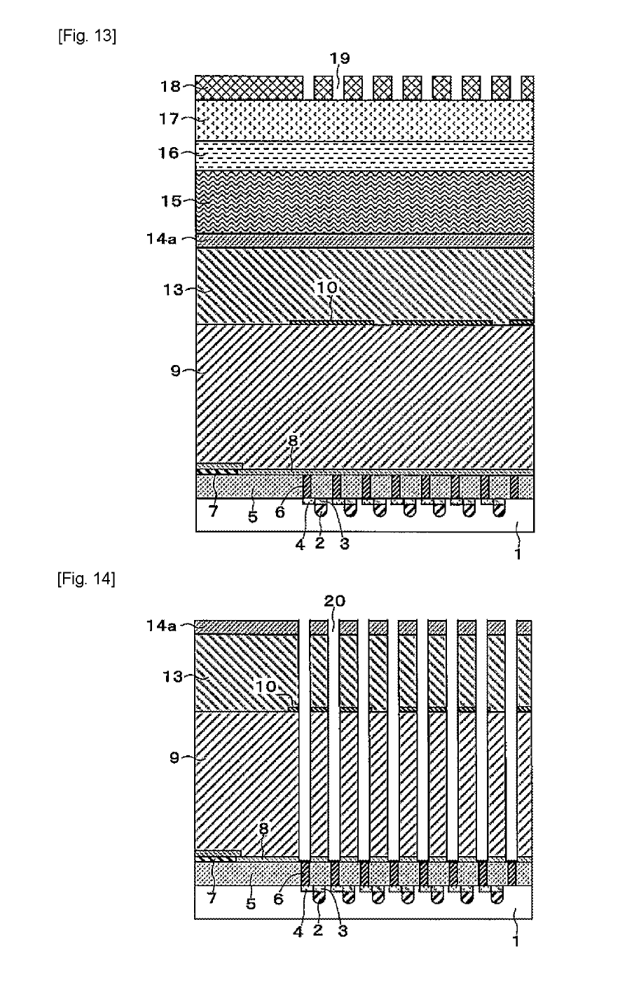

Next, as shown in FIG. 14, the antireflection film 17, second hard mask film 16, first hard mask film 15 and second insulating film 14a are etched in succession using the second mask film 18 as a mask, and the cylinder hole pattern 19 is transferred to the second insulating film 14a. The hard mask films 15, 16 remaining on the second insulating film 14a are removed, after which the second sacrificial film 13, second support film 10, first sacrificial film 9 and silicon nitride film 8 are etched in succession using as a mask the second insulating film 14a on which the cylinder hole pattern 19 is formed, and cylinder holes 20 reaching to the contact plugs 6 are formed.

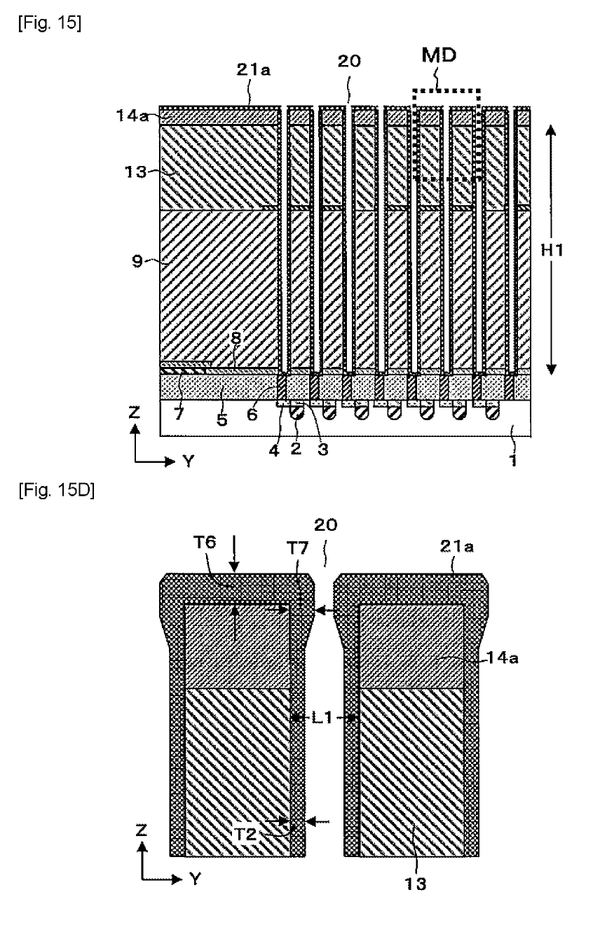

Next, as shown in FIG. 15, a lower electrode material film 21a is formed over the whole surface including within the cylinder holes 20. FIG. 15D is an enlargement of an opening region MD of one cylinder hole 20 in FIG. 15. In the case of an F25 nm-generation DRAM in which the minimum processing dimension F governed by the resolution limit of lithography techniques is 25 nm, for example, the cylinder hole 20 must be formed in such a way that the diameter L1 is around 50 nm and the depth H1 is around 1500 nm. If a predetermined film thickness T2 is to be formed on the inner surface of the cylinder hole 20 when a lower electrode material film 21a is formed in this kind of cylinder hole 20, then a lower electrode material film 21a having a film thickness T7 which is approximately twice as large ends up being formed at the upper ends where film formation readily occurs. A lower electrode material film 21a having a film thickness T6 which is even greater than T7 is formed on the upper surface of the second insulating film 14a. That is to say, it is difficult to form a film having good coverage on a cylinder hole 20 having a high aspect ratio (up to 30). For this reason, the openings at the upper ends are closed off in a subsequent step when a capacitance insulating film is formed on the lower electrodes 21, and it is no longer possible to form an upper electrode inside the cylinder hole 20. In other words, there is a problem in that a capacitor cannot be formed. This problem does not arise if the cylinder holes 20 have a relatively large diameter, but the problem is pronounced in semiconductor devices of a miniaturized generation having cylinder holes 20 of reduced diameter.

Next, as shown in FIG. 16, a protective film 22a is formed in such a way as to cover the lower electrode material film 21a and close off the openings. A mask film 23 having a pattern including first openings 24 and a peripheral opening 24a is formed on the protective film 22a by means of a third lithography step.

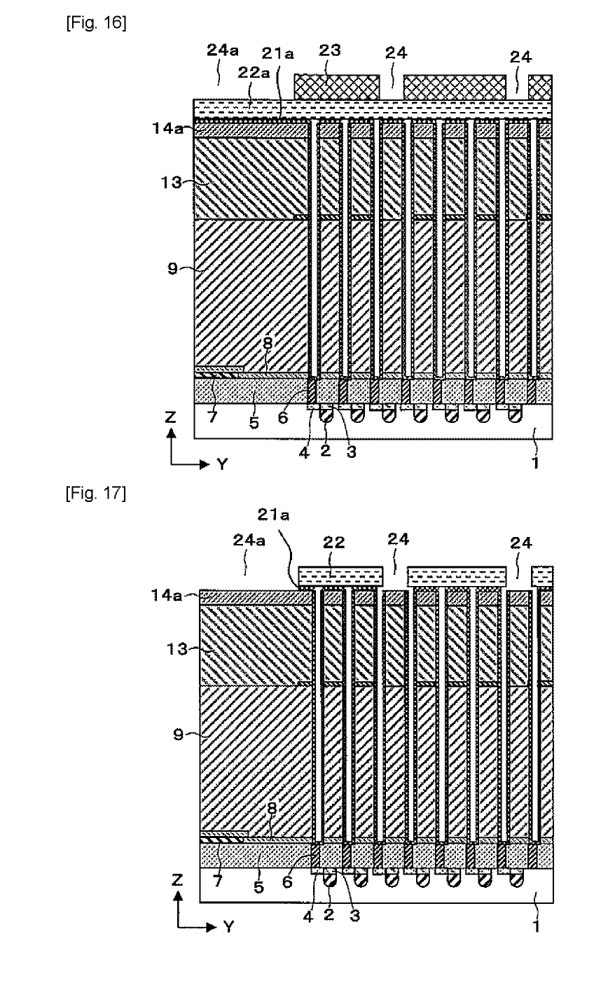

Next, as shown in FIG. 17, the protective film 22a which is exposed within the first openings 24 and the peripheral opening 24a is etched using the mask film 23 as a mask. As a result, the protective film 22 having a first opening pattern is formed. The lower electrode material film 21a which is exposed at the upper surface is further etched, and the second insulating film 14a is exposed within the first openings 24 and the peripheral opening 24a.

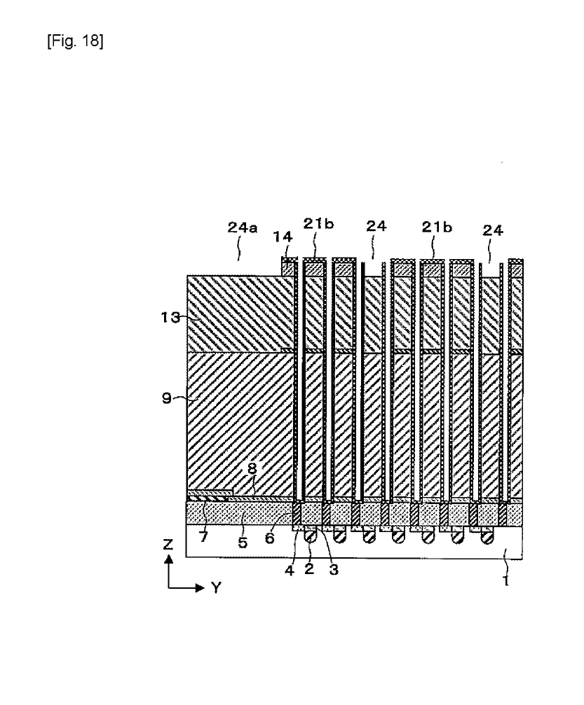

Next, as shown in FIG. 18, the second insulating film 14a which is exposed within the first openings 24 and the peripheral opening 24a is etched. The protective film 22 is also simultaneously etched and destroyed by this etching. As a result, the upper surface of the second sacrificial film 13 is exposed within the first openings 24 and the peripheral opening 24a. Furthermore, a lower electrode material film 21b is exposed in regions outside the first openings 24 and the peripheral opening 24a. A first support film 14 which is contiguous with the upper ends of the plurality of lower electrodes (21) is further formed.

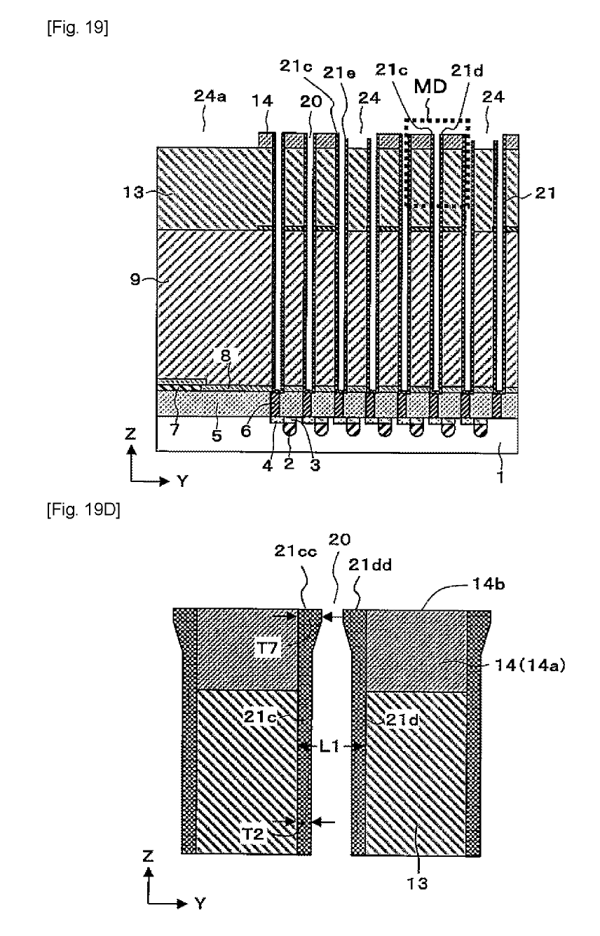

Next, as shown in FIG. 19, the lower electrode material film 21b which is formed on the first support film 14 is etched in regions outside the first openings 24 and the peripheral opening 24a. As a result, independent lower electrodes 21 are formed inside the respective cylinder holes 20. The lower electrodes 21 formed in regions outside the first opening 24 include lower electrode portions 21c and 21d having an upper surface which is flush with the upper surface of the first support film 14 while also touching the first support film 14. Furthermore, the lower electrodes 21 which are partly formed inside the first openings 24 include the lower electrode portion 21c having an upper surface which is flush with the upper surface of the first support film 14 while also touching the first support film 14, and a lower electrode portion 21e having an upper surface at a position lower than the upper surface of the first support film 14 and not in contact with the first support film 14.

FIG. 19D is an enlargement of the opening region MD of one cylinder hole 20 positioned in a region outside the first openings 24 in FIG. 19. At the stage in FIG. 15D, the lower electrode material film 21a which is formed on the upper surface of the second insulating film 14a is removed, and an upper surface 14b of the first support film 14 and upper surfaces 21cc, 21dd of the lower electrodes are flush. At this point, the lower electrode portions 21c, 21d having a film thickness T7 which is greater than the film thickness T2 are formed on the side surfaces at the upper ends of the first support film 14 inside the cylinder hole 20.

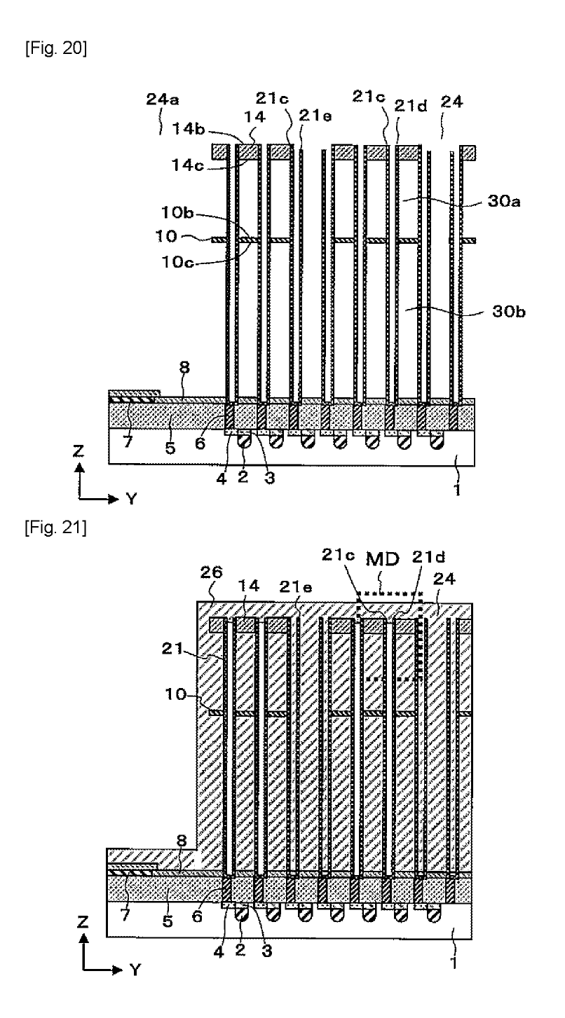

Next, as shown in FIG. 20, etching solution is diffused from the first openings 24 and the peripheral opening 24a, and the second sacrificial film 13 and first sacrificial film 9 are completely removed. As a result, upper surfaces 14b and lower surfaces 14c of the first support film 14 which is contiguous with the upper ends of the lower electrodes 21 are exposed, while upper surfaces 10b and lower surfaces 10c of the second support film 10 which is contiguous with intermediate parts of the lower electrodes 21 are also exposed. Furthermore, the upper surface of the silicon nitride film 8 is exposed. As a result, a series of first voids 30a are formed on the outside of the plurality of lower electrodes 21 positioned between the first support film 14 and the second support film 10, and a series of second voids 30b are formed on the outside of the plurality of lower electrodes 21 positioned between the second support film 10 and the silicon nitride film 8. The inside and outside surfaces of the lower electrodes 21 which are not in contact with the first support film 14 and second support film 10 are exposed at these voids 30a, 30b.

Next, as shown in FIG. 21, a capacitance insulating film (25 in FIG. 23) is formed on the surface of the structure comprising the lower electrodes 21, first support film 14 and second support film 10, in other words over the whole surface including the voids 30a, 30b. An upper electrode 26 is then formed in such a way as to cover the surface of the capacitance insulating film.

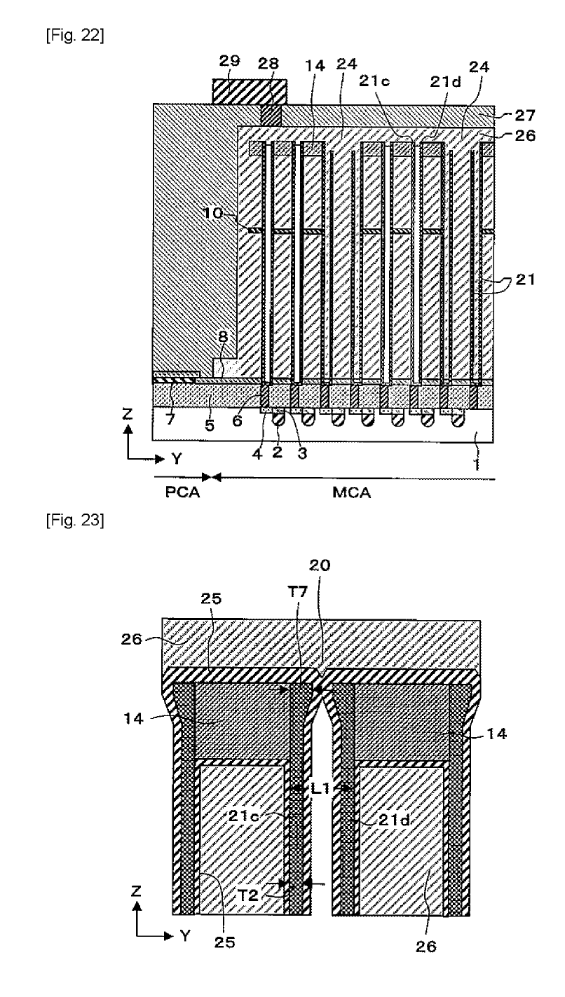

Next, as shown in FIG. 22, a second interlayer insulating film 27, a via plug 28 and upper-layer wiring 29 are formed. A capacitor having crown-shaped lower electrodes 21 is formed in this way.

The following problems arise with this experimental example.

Firstly, the pattern of the second openings 12 and the cylinder hole pattern 19 are formed using separate lithography steps. Consequently, positional offset is produced in the patterns, and in extreme cases the cylinder holes 20 are formed at positions removed from the second openings 12, and lower electrodes 21 which are not contiguous with the second support film 10 are formed. In this case, the second support film 10 does not function as a support and twisting is produced in the lower electrodes 21.

Secondly, there is a problem in that the openings of the cylinder holes become closed off so a capacitor is not formed. FIG. 23 shows an enlargement of the region MD at the stage of FIG. 21. The lower electrode portions 21c, 21d having a thickness T7 are formed on the side surfaces at the upper ends of the first support film 14, thereby narrowing the openings of the cylinder holes 20, and the openings are closed off when the capacitance insulating film 25 is formed so a situation arises in which the upper electrode 26 is not formed inside the cylinder holes 20.

The capacitance insulating film 25 and the upper electrode 26 are formed inside the voids 30a, 30b positioned on the outside of the cylinder holes 20, so a capacitor function is achieved. However, only the capacitance insulating film 25 is formed inside the cylinder holes 20, while the upper electrode 26 is not formed, so a capacitor function is not achieved. The resulting capacitor is defective because it cannot hold the capacitance required for DRAM operation.

### First Mode of Embodiment of the Present Invention

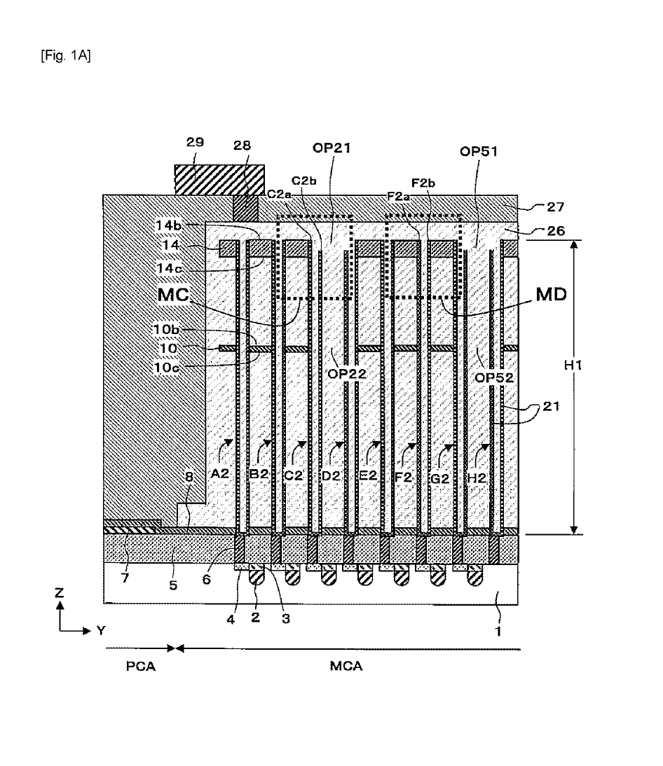

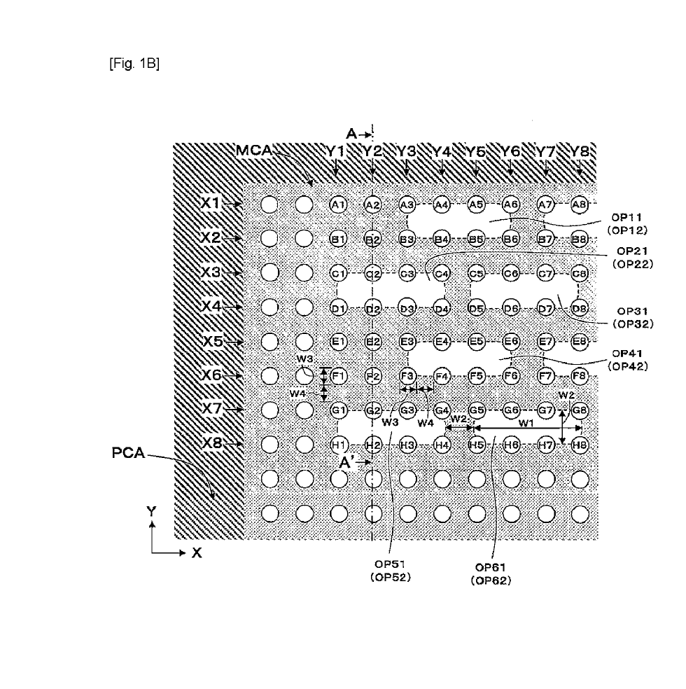

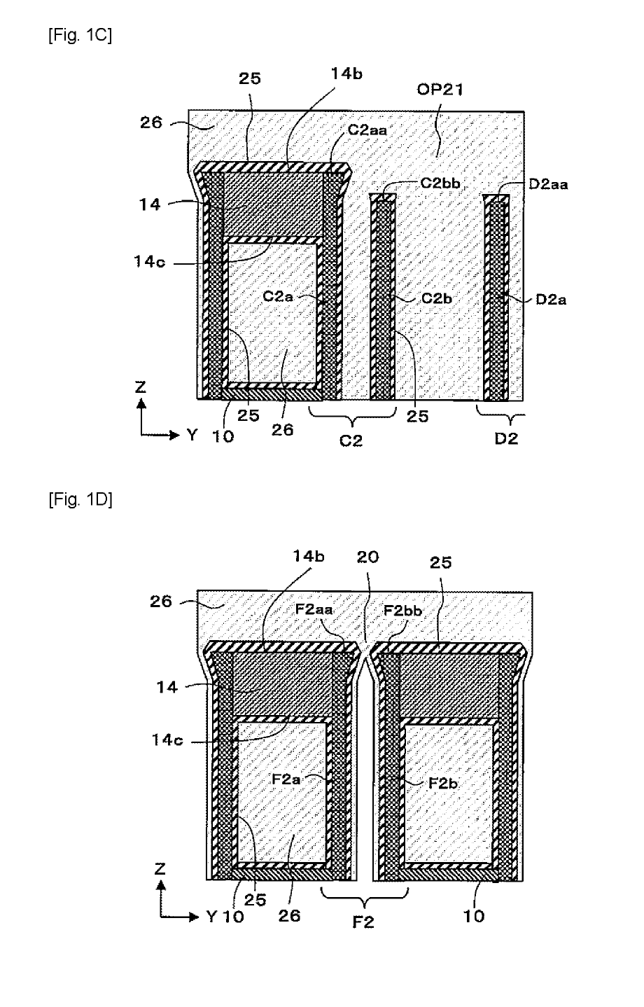

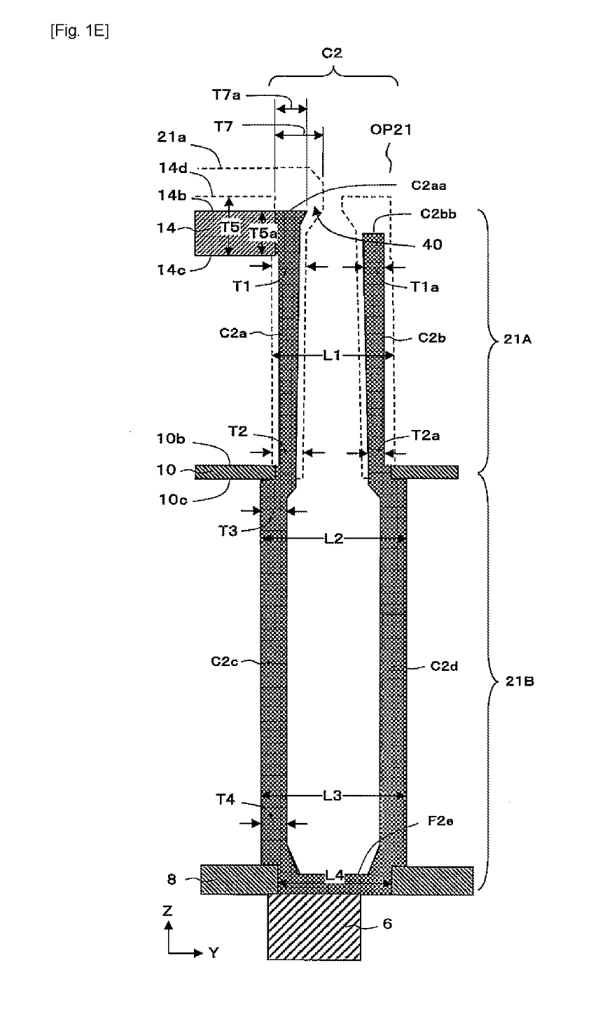

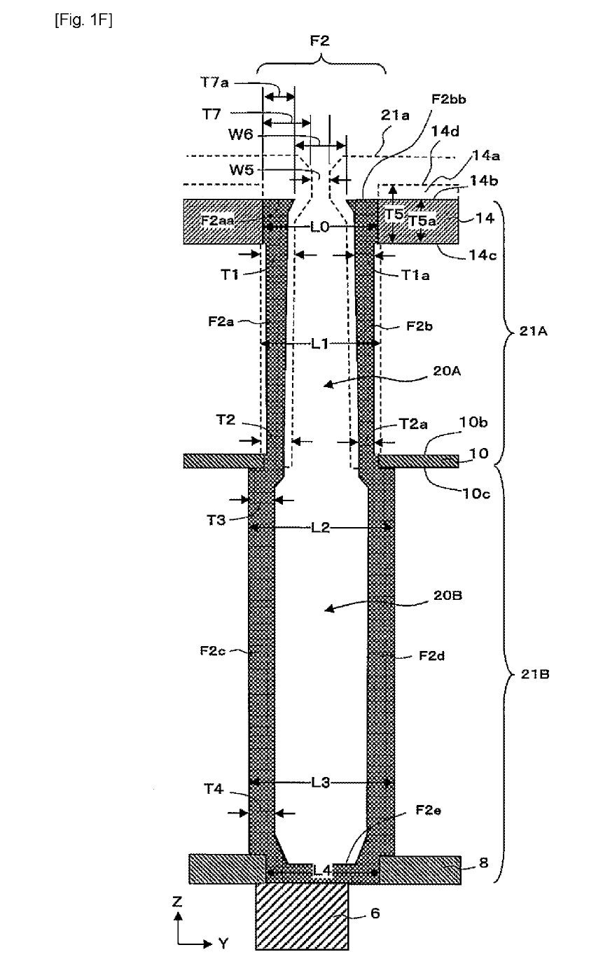

A first mode of embodiment of the present invention will be described with the aid of FIG. 1A to 10A. Each “A” diagram is a view in cross section along the line A-A′ of the corresponding “B” diagram (plan view). Each “C” diagram is an enlargement in cross section of a region MC shown in the corresponding “A” diagram, and each “D” diagram is an enlargement in cross section of a region MD shown in the corresponding “A” diagram.

### Semiconductor Device

The configuration of the semiconductor device according to this mode of embodiment will be described with the aid of FIG. 1A-1F. The semiconductor device according to this mode of embodiment is a DRAM.

FIG. 1A shows a cross section A-A′ of the plan view shown in FIG. 1B to be described later. In the same way as in the experimental example described above, the DRAM has a peripheral circuit area PCA and a memory cell area MCA in which a plurality of capacitors are formed. A plurality of embedded gate electrodes 2 and a cap insulating film 3 which covers the upper surfaces of the embedded gate electrodes 2 are provided on the surface of a semiconductor substrate 1 positioned in the memory cell area MCA. An impurity diffusion layer (referred to below as a “diffusion layer”) 4 forming the source or drain of a transistor is provided on the semiconductor substrate 1 adjacent to the cap insulating film 3. A plurality of contact plugs 6 which pass through a first interlayer insulating film 5 formed on the semiconductor substrate 1 and are contiguous with the diffusion layer 4 are provided. A bit line which is not depicted is formed within the first interlayer insulating film 5. A peripheral circuit 7 is provided on the first interlayer insulating film 5 in the peripheral circuit area PCA. A stopper silicon nitride film 8 is provided in such a way as to cover the first interlayer insulating film 5, contact plugs 6 and peripheral circuit 7. Eight lower electrodes 21 from A2 to H2 which pass through the stopper silicon nitride film 8 and are contiguous with the upper surfaces of the contact plugs 6 are disposed at a predetermined arrangement pitch in the Y-direction (first direction) parallel with the surface of the semiconductor substrate 1. It should be noted that in the following description, the reference symbols A2 to H2 given as the lower electrodes 21 may be given as the reference symbols for the corresponding capacitors. Furthermore, the reference symbols A2 to H2 may be given as the lower electrodes.

The upper ends of the lower electrodes 21 are connected to one another by a first support film 14. Furthermore, a second support film 10 is provided at an intermediate position of the lower electrodes 21 in the Z-direction (third direction) which is a direction perpendicular to the surface of the semiconductor substrate 1, thereby connecting the lower electrodes 21 to one another. The second support film 10 has the same pattern as the first support film 14 and is thinner than the first support film 14. The thickness of the second support film 10 ranges from 1/10-½ of the thickness of the first support film 14. For example, if the thickness of the first support film 14 is 100 nm, then the thickness of the second support film 10 may be set at 10-50 nm. Furthermore, the second support film 10 is disposed at a position which is at a higher level than half of the height of the lower electrodes 21 and at a lower level than one quarter of the height from the upper ends thereof. For example, if the height H1 of the lower electrodes 21 is 1600 nm, then the second support film 10 is disposed at a position which is greater than 400 nm and less than 800 nm from the upper ends.

The first support film 14 has first openings OP21, OP51. Furthermore, the second support film 10 has second openings OP22, OP52 in the same pattern as the first openings OP21, OP51 and at overlapping positions which are aligned in the Z-direction. Part of the upper surfaces of the lower electrodes C2, D2, G2, H2 are exposed within the first openings OP21, OP51. Looking at the lower electrode C2 for example, this lower electrode includes a first portion C2a whereof the upper surface is not positioned within the first opening OP21 and a second portion C2b whereof the upper surface is positioned within the first opening OP21, as seen on a plane viewed from above in the Z-direction. The outer circumference of the first portion C2a is connected to the first support film 14 and the upper surface is flush with the upper surface of the first support film 14, but the second portion C2b is not connected to the first support film 14 and the upper surface thereof is positioned at a lower level than an upper surface 14b and at a higher level than a lower surface 14c of the first support film 14. In this way, a capacitor formed by lower electrodes having a first surface which is flush with the upper surface of the first support film 14 and a second surface at a lower level than the upper surface of the first support film 14 is provided as a first capacitor. The lower electrodes forming the first capacitor have a ring-shaped upper surface in plan view and the first upper surface of one lower electrode constitutes a partial upper surface of a lower electrode positioned outside the first opening, while the second upper surface constitutes another partial upper surface of a lower electrode positioned within the first opening.

Meanwhile, the upper surfaces of the lower electrodes A2, B2, E2, F2 are not positioned within the openings OP21, OP51, when seen in plan view. Looking at the lower electrode F2 for example, this lower electrode includes a portion F2a and a portion F2b whereof the upper surfaces are not positioned within the opening OP51. The whole circumference of the upper ends on the side surfaces of the lower electrodes which are not positioned within the openings OP21, OP51 is connected to the first support film 14, and the upper surfaces are flush with the upper surface of the first support film 14. A capacitor having lower electrodes formed in this way is provided as a second capacitor. That is to say, a memory cell according to this exemplary embodiment is formed by the first capacitor and the second capacitor.

The individual lower electrodes are formed with a crown structure and the inner and outer surfaces of each lower electrode, the upper and lower surfaces of the first support film 14, the upper and lower surfaces of the second support film 10, and the upper surface of the stopper silicon nitride film 8 are covered by a capacitance insulating film which is not depicted, and an upper electrode 26 further covers the surface of the capacitance insulating film. A second interlayer insulating film 27 is provided in such a way as to cover the upper electrode 26. A via plug 28 which is connected to the upper electrode 26 is provided running through the second interlayer insulating film 27, and upper-layer wiring 29 which is connected to the upper surface of the via plug 28 is provided in order to construct the outline of a DRAM. The lower electrodes 21 forming the crown-structure capacitor in this mode of embodiment are constructed by cylinders having a bottom surface, the upper end surface being ring-shaped in plan view.

The plan view in FIG. 1B will be referred to next. To facilitate the description, FIG. 1B is a drawing in which part of the memory cell area MCA and peripheral circuit area PCA has been extracted. FIG. 1B is a plan view showing a situation in which the upper surface of the first support film 14 is exposed. Lower electrodes (indicated by circles) corresponding to a plurality of capacitors arrayed in the Y-direction and the X-direction (second direction) perpendicular to the Y-direction are disposed in the memory cell area MCA. For example, lower electrodes A1-A8 are disposed in the row X1, while the lower electrodes A2-H2 shown in FIG. 1A are disposed in the column Y2. FIG. 1B shows the arrangement layout of first openings OP11, OP21, OP31, OP41, OP51 and OP61. A duplicate description of the second openings will be omitted because they have the same pattern and the same layout as the first openings, but the following description likewise applies to the second openings (OP12, OP22, OP32, OP42, OP52 and OP62).

When seen in plan view, the first openings are formed by a rectangular shape having long sides in the X-direction parallel to the surface of the semiconductor substrate, and short sides in the Y-direction perpendicular to the X-direction. Looking at the row Y2 corresponding to the cross section in FIG. 1A, the lower electrodes A2, B2, E2, F2 whereof the upper surfaces are not positioned within the first openings and the lower electrodes C2, D2, G2, H2 whereof the upper openings are partially positioned within the first openings are arranged in a regular fashion in the Y-direction. Looking at the first opening OP21 for example, the pattern of the first opening OP21 is constructed in such a way that part of the upper surfaces of two lower electrode unit groups which are adjacently arranged in the Y-direction are positioned together inside the first opening, where four lower electrodes adjacent in the X-direction from among the plurality of lower electrodes which are arranged at equal intervals on straight lines in the Y-direction and X-direction constitute a lower electrode unit group. That is to say, part of the upper surfaces of a first lower electrode unit group comprising the four lower electrodes C1, C2, C3, C4 which are adjacent in the X-direction, and part of the upper surfaces of a second lower electrode unit group comprising the four lower electrodes D1, D2, D3, D4 which are adjacently arranged in the Y-direction are positioned together inside the first opening.

Four lower electrodes which are positioned on the long sides of the first opening and are split in half in the radial direction and have half of the ring-shaped lower electrode upper surface seen in plan view positioned in said first opening, and four lower electrodes which are positioned at the corners of the first opening and have one quarter of the ring-shaped lower electrode upper surface positioned in said first opening, are therefore included in the first opening. That is to say, half of the ring-shaped lower electrode upper surface of C2, C3, D2, D3 is positioned within the first opening OP21, and one quarter of the ring-shaped lower electrode upper surface of C1, C4, D1, D4 is likewise positioned within the first opening OP21.

If W3 is the diameter of an individual lower electrode, and W4 is the interval between two nearest-neighbor adjacent lower electrodes, then the arrangement pitch of the lower electrodes in plan view is defined by W3+W4, and the width of the first opening in the X-direction, i.e. the width W1 of the long sides, is equal to three times the arrangement pitch of the lower electrodes. Furthermore, the width in the Y-direction, i.e. the width W2 of the short sides, is equal to W3+W4, which is the arrangement pitch of the lower electrodes. The intervals of adjacent first openings in the X-direction are also equal to the arrangement pitch W2 of the lower electrodes. The intervals of the first openings adjacently arranged in the Y-direction are also equal to the arrangement pitch W2 of the lower electrodes. However, the plurality of first openings adjacent in the Y-direction are not all provided on a straight line, rather they are each staggered with an offset of two-thirds of W1 in the X-direction (twice the arrangement pitch of the lower electrodes). For example, the first opening OP41 adjacent in the Y-direction to the first opening OP51 is disposed at a position offset in the X-direction by twice W2. In addition, the first opening OP31 adjacent in the Y-direction is disposed at a position offset in the X-direction by twice W2. From a different perspective, every other first opening disposed in the Y-direction is aligned on a straight line. The center line of the first openings in the X-direction does not intersect the nearest adjacent neighbor in the Y-direction, and the center line in the X-direction of every other first opening is aligned.

As indicated above, the first support film 14 and the second support film 10 according to this exemplary embodiment are not split up into straight lines, rather they form contiguous flat beams which are connected to all the lower electrodes disposed inside one memory cell area.

The present inventors investigated various types of first openings having a different shape and layout to the first openings having the arrangement described above, but it was found that different combinations of pattern shapes and irregular layouts than those shown in FIG. 1B made it difficult to improve capacitor production yield, and therefore they arrived at the present invention.

FIG. 1C will be referred to next. FIG. 1C is an enlargement in cross section of the region MC at the upper end of the lower electrode C2 shown in FIG. 1A. The lower electrode C2 forming part of the first capacitor comprises a first portion C2a whereof a first upper surface C2aa is not positioned within the first opening OP21, and a second portion C2b whereof a second upper surface C2bb is positioned within the first opening OP21. The side-surface upper end of the first portion C2a is connected to the first support film 14, while the first upper surface C2aa is flush with the upper surface 14b of the first support film 14. Meanwhile, the upper end of the second portion C2b is not connected to the first support film 14, and the second upper surface C2bb is disposed at a position at a lower level than the upper surface 14b and at a higher level than the lower surface 14c of the first support film 14.

The lower electrode C2 forming part of the first capacitor comprises the first upper surface C2aa which is flush with the upper surface 14b of the first support film 14, and the second upper surface C2bb which is positioned at a lower level than the upper surface 14b of the first support film 14. This means that a difference in height is produced in the positions of the upper ends of the first portion C2a and the second portion C2b, so it is possible to avoid proximity between the first portion C2a and the second portion C2b and there are no problems in terms of closure even when the capacitance insulating film 25 and the upper electrode 26 are provided. Two lower electrodes which are opposing in the Y-direction within a single first opening constitute lower electrodes opposite each other with a second upper surface. For example, the lower electrodes C2 and D2 are opposing in the Y-direction within the first opening OP21, and among each of the lower electrodes, the second portion C2b having the second upper surface C2bb and another second portion D2a having the second upper surface D2aa are opposite each other.

FIG. 1D will be referred to next. FIG. 1D is an enlargement in cross section of the region MD at the upper end of the lower electrode F2 shown in FIG. 1A. The lower electrode F2 forming part of the second capacitor comprises a first portion F2a and a second portion F2b whereof upper surfaces F2aa and F2bb are not positioned within the first opening. The side-surface upper ends of the first portion F2a and the second portion F2b are both connected to the first support film 14, and the upper surfaces F2aa and F2bb are flush with the upper surface 14b of the first support film 14. In this case, the upper end of the first portion F2a is close to the upper end of the second portion F2b in the same way as in the experimental example described above. However, in this mode of embodiment, the lower electrode F2 comprises the first support film 14 which is degraded in the Z-direction as will be described later, and the first portion F2a and second portion F2b which are degraded in the Y-direction and the Z-direction, so an interval is maintained by restricting proximity between the first portion F2a and the second portion F2b. This means that it is possible to construct a capacitor by arranging the upper electrode 26 on the inner surface of the lower electrode F2 while avoiding closure as a result of the capacitance insulating film 25 being provided, even in the case of the second capacitor.

FIG. 1E will be referred to next. FIG. 1A is an enlargement in cross section of the whole of the lower electrode C2 forming part of the first capacitor.

The lower electrode C2 forming part of the first capacitor extends in the Z-direction perpendicular to the semiconductor substrate surface, and the second support film 10 is connected to the outer circumferential side surface of the lower electrode lying at an intermediate position in the Z-direction. Furthermore, the first support film 14 is connected to part of the side surface of the lower electrode positioned at the upper end in the Z-direction. The upper surface of the lower electrode forming part of the first capacitor is formed by the first upper surface C2aa which is flush with the upper surface 14b of the first support film 14, and the second upper surface C2bb which is at a lower level than the upper surface 14b of the first support film. The bottom surface of the lower electrode C2 is connected to the upper surface of the contact plug 6.

The capacitor C2 having the lower electrode C2 as a constituent element thereof is formed by a lower capacitor 21B positioned between the upper surface of the contact plug 6 and the lower surface 10c of the second support film 10, and an upper capacitor 21A positioned between the lower surface 10c of the second support film 10 and the upper surface 14b of the first support film 14. T1a is the film thickness of the lower electrodes of the upper capacitor 21A at a position in proximity to the first support film 14, and T2a is the film thickness of the lower electrodes at a position in proximity to the second support film 10. Furthermore, T3 is the film thickness of the lower electrodes of the lower capacitor 21B at a position in proximity to the second support film 10, and T4 is the film thickness of the lower electrodes at a position in proximity to the contact plug 6. In this mode of embodiment, T2a is the smallest from among T1a, T2a, T3 and T4.

In FIG. 1E, the dotted line 14d indicates the position of the upper surface of the first support film 14 prior to degradation. Furthermore, the dotted line 21a indicates the position of the upper surface at the time when the lower electrode material film is formed. When the lower electrode material film is formed, the thickness of the support film 14 is T5 and the thickness of an increased-width part 40 of the lower electrode material film 21a at the position of the side surface of the first support film 14 is T7. Furthermore, the film thickness at the upper part of the portions C2a, C2b of the lower electrode C2 forming part of the upper capacitor 21A is T1, and the film thickness of the lower part thereof is T2, while the film thickness at the upper part of the portions C2c and C2d of the lower electrode forming part of the lower capacitor 21B is T3, and the film thickness of the lower part thereof is T4. When the lower electrode material film 21a is formed, T1>T2>T3≧T4. In the experimental example described above, the lower electrode C2 is formed while this relationship is maintained. According to this mode of embodiment, the first support film 14 is degraded in such a way that the thickness thereof changes from T5 to T5a. That is to say, the upper surface C2aa of the lower electrode C2a is degraded to a position which is flush with the upper surface 14b of the first support film 14. In addition, the upper capacitor 21A is also degraded in the Y-direction in such a way that T1 changes to T1a and T2 changes to T2a. As a result, the film thickness relationship of each part of the lower electrode C2 in this mode of embodiment is such that T1a≧T3≧T4>T2a. It should be noted that the scale in the drawings is not accurate.

The lower electrodes in this mode of embodiment have a diameter (outer diameter) L1 of the lower electrode forming part of the upper capacitor 21A, a diameter L2 of the lower electrode forming part of the lower capacitor 21B at a position in proximity to the second support film 10 and a diameter L3 at a position in proximity to the stopper silicon nitride film 8, and a diameter L4 defined by the diameter of a contact hole provided in the stopper silicon nitride film 8. The size relationships of these diameters are such that L2>L1>L3>L4, and the dimensions are such that the lower electrode has the largest diameter at the upper part of the lower capacitor 21B positioned below the second support film 10. It should be noted that “a position in proximity” means a position 50 nm away in the description above. For example, a position of the lower electrode forming part of the lower capacitor 21B in proximity to the second support film 10 means a position 50 nm below the lower surface 10c of the second support film 10. In this case too the scale of the drawings is not accurate.

FIG. 1F will be referred to next. FIG. 1F is an enlargement in cross section of the whole of the lower electrode F2 corresponding to the second capacitor.

The structure of the lower electrode F2 corresponding to the second capacitor below the first support film 14 is the same as that of the lower electrode C2 corresponding to the first capacitor and will therefore not be described. The difference lies in the fact that the lower electrodes do not have an upper surface which lies within the first opening OP. The upper ends on the outer circumferential side surface of the lower electrode F2 are therefore connected to the side surface of the first support film 14 around the whole circumference. In the experimental example described above, the opening width W5 of the cylinder hole when the lower electrode indicated by the dotted line 21a is formed is maintained, so the opening is closed off at the stage when the capacitance insulating film is formed and it is no longer possible to form the upper electrode inside the cylinder hole. However, in this mode of embodiment, the lower electrode of the upper capacitor 21A is degraded in the Z-direction and the Y-direction, as described in relation to FIG. 1E, so the opening width of the cylinder hole can be increased to W6. As a result, closure of the cylinder hole opening is avoided even if the capacitance insulating film is formed so it is possible to produce a capacitor in which the upper electrode can be provided inside the cylinder hole. It should be noted that the relationship T1a≧T3≧T4>T2a is still maintained for the second capacitor in the same way as the first capacitor, and the relationship L2>L1>L0>L3>L4 is also maintained. For example, if T1a is 100% of the film thickness, T3 is around 97%, T4 is around 94% and T2a is around 85%. Furthermore, if L0 is 100% of the width, L1 is around 110%, L2 is around 120%, L3 is around 80%, and L4 is around 70%.

### Method for Producing a Semiconductor Device

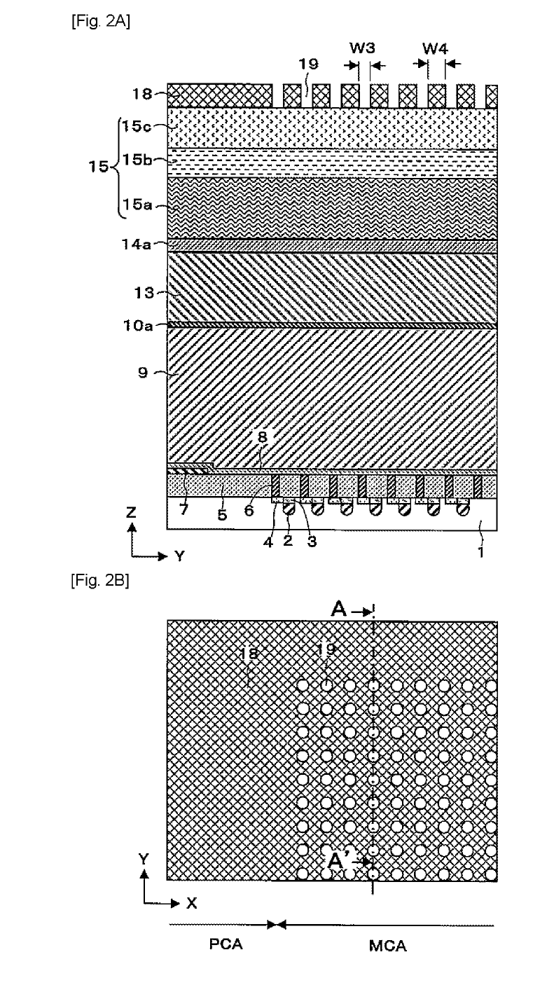

The method for producing a semiconductor device according to the first mode of embodiment of the present invention will be described in detail next with reference to FIG. 2-10. Here, a DRAM (Dynamic Random Access Memory) is described as an example of a semiconductor device, but the present invention may equally be applied to semiconductor devices other than a DRAM in which a structure having a high aspect ratio is supported by a plurality of support films.

The DRAM comprises a memory cell area MCA in which a plurality of memory cells are disposed and a peripheral circuit area PCA for driving the memory cells. FIG. 2-10 are partial views of the area around the boundary portion between the memory cell area MCA and the peripheral circuit area PCA in a DRAM undergoing production. In the figures, “A” diagrams are views in cross section along the line A-A′ of the plan view shown in “B” diagrams, “C” diagrams are enlargements in cross section of the area MC shown in the “A” diagrams, and “D” diagrams are enlargements in cross section of the region MD shown in the “A” diagrams.

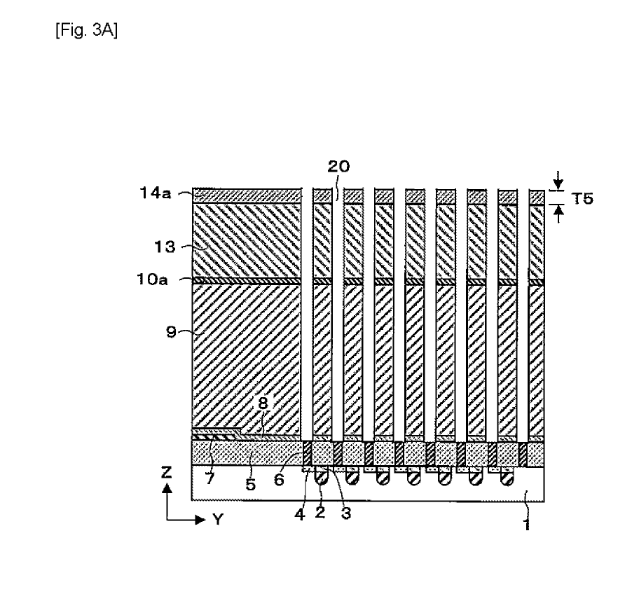

A cylinder hole formation step is performed first of all, as shown in FIGS. 2A, 2B and 3A.

Specifically, as shown in FIGS. 2A and 2B, embedded gate electrodes 2, a cap insulating film 3 and an impurity diffusion layer 4 etc. are formed in the memory cell area of a semiconductor substrate 1. Furthermore, a first interlayer insulating film 5 is formed on the semiconductor substrate 1 and contact plugs 6 are formed passing therethrough. A peripheral circuit 7 etc. is formed in the peripheral circuit area PCA. The following stack of layers is also formed in succession: a stopper silicon nitride film 8 having a thickness of 50 nm, for example; a first cylinder interlayer film (first sacrificial film) 9 having a thickness of 900 nm, for example; a first insulating film 10a comprising silicon nitride having a thickness of 30 nm, for example; a second cylinder interlayer film (second sacrificial film) 13 having a thickness of 500 nm, for example; a second insulating film 14a comprising silicon nitride having a thickness of 150 nm, for example; a hard mask film 15; and an organic mask film 18. The hard mask film 15 is formed by a stack of films comprising an amorphous silicon film 15a, a silicon dioxide film 15b and an amorphous carbon film 15c.

The first sacrificial film 9 and the second sacrificial film 13 are formed in such a way as to be divided above and below with the first insulating film 10a as a boundary therebetween. The first sacrificial film 9 is formed by a lower first sacrificial film which has a relatively fast wet etching rate and a thickness of 500 nm, for example, and an upper first sacrificial film which has a relatively slow wet etching rate and a thickness of 400 nm, for example. A silicon dioxide film which contains boron (B) and phosphorus (P) and is formed by CVD (Chemical Vapor Deposition) (BPSG film: BoroPhosphoSilicate Glass) may be used for the lower first sacrificial film and the upper first sacrificial film. The lower first sacrificial film is formed in such a way as to have high B and P concentrations while the upper first sacrificial film is formed in such a way as to have low B and P concentrations. The wet etching rate is increased the higher the B and P concentrations. Furthermore, an undoped silicon dioxide film is used for the second sacrificial film 13. As a result, the lower first sacrificial film has the fastest wet etching rate, while the etching rates of the upper first sacrificial film and the undoped silicon dioxide film are successively slower. It should be noted that known technology may be used in order to form each of these layers.

After the organic mask film 18, which is the uppermost layer, has been formed, a pattern 19 comprising a plurality of cylinder holes is formed on the organic mask film 18 positioned in the memory cell area MCA by means of a first lithography step. Here, the diameter W3 of the cylinder hole pattern 19 is set at 50 nm, for example. Furthermore, the interval W4 is set at 30 nm, for example.

According to this mode of embodiment, neither the first insulating film 10a nor the second insulating film 14a is subjected to a pattern formation step, unlike in the experimental example described above, and the second sacrificial film 13 and hard mask film 15 are formed on the respective upper surfaces thereof.

The semiconductor substrate 1 is a p-type single-crystal silicon substrate, for example. The semiconductor substrate 1 is electrically isolated by means of an element isolation region (not depicted) into the memory cell area MCA and the peripheral circuit area PCA. The embedded gate electrodes 2 and diffusion layer 4 formed in the memory cell area MCA constitute a transistor. Furthermore, the embedded gate electrodes 2 also function as word lines. The contact plugs 6 are connected to the diffusion layer 4 while also being connected to the lower electrodes of the capacitor at a later step. It should be noted that a bit line which is not depicted is formed within the first interlayer insulating film 5. The stopper silicon nitride film 8 is formed over the whole surface of the semiconductor substrate 1 using CVD, for example. The first insulating film 10a is formed using CVD, for example. The first insulating film 10a may equally be formed using sputtering or an HDP (High Density Plasma) technique. A film formed using sputtering or an HDP technique has a high density and the solution etching rate thereof can be reduced in comparison with a film formed by means of CVD. Furthermore, the first insulating film 10a is not patterned at this point, unlike in associated methods for producing a semiconductor device.

The second insulating film 14a is formed by the same method as the first insulating film 10a. The second insulating film 14a is not patterned either at this point. The amorphous silicon film 15a is formed to a thickness of 1000 nm by means of CVD, for example. The silicon dioxide film 15b is formed to a thickness of 50 nm by means of CVD, for example. The amorphous carbon film 15c is formed to a thickness of 500 nm by means of plasma CVD, for example.

The organic mask film 18 is formed by a film stack including a photoresist and a silicon-containing antireflection film etc. The openings forming the cylinder hole pattern 19 correspond to the position of capacitor formation. The diameter of the openings may be set at 40-80 nm and the closest interval between adjacent openings may be set at 20-40 nm. It is difficult to repeatedly arrange linear beams in the X-direction and Y-direction with a close-packed pattern in which a large number of openings are provided in this way with associated methods for producing a semiconductor device having a narrow interval between adjacent openings, in other words a narrow interval between capacitors. According to this mode of embodiment, a structure is produced in which openings are formed in the support films and planar support is provided rather than beam support, as will be described later.

Next, as shown in FIG. 3A, the amorphous carbon film 15c is etched by means of anisotropic dry etching employing oxygen-containing plasma and using the organic mask film 18 as a mask. In addition, the silicon dioxide film 15b is subjected to anisotropic dry etching using fluorine-containing plasma, and the cylinder hole pattern 19 is transferred to the silicon dioxide film 15b. After this, the organic mask film 18 and the amorphous carbon film 15c are removed. The amorphous silicon film 15a is then subjected to anisotropic dry etching using the silicon dioxide film 15b as a mask, and the cylinder hole pattern 19 is transferred to the amorphous silicon film 15a.

Next, the second insulating film 14a, second sacrificial film 13, first insulating film 10a, first sacrificial film 9 and stopper silicon nitride film 8 are etched in succession by means of anisotropic dry etching using the silicon dioxide film 15b and the amorphous silicon film 15a as a mask, whereby the cylinder holes 20 are formed. As a result of this etching, the silicon dioxide film 15b and the amorphous silicon film 15a are destroyed and the upper surface of the second support film 14a is exposed. At this stage the film thickness T5 of the second support film is 130 nm. Furthermore, the upper surfaces of the contact plugs 6 are exposed at the bottom surface of the cylinder holes 20.

Next, wet cleaning to remove the residue from dry etching is carried out, and a wet treatment employing a hydrofluoric acid (HF)-containing solution, which serves as pre-cleaning before the lower electrode material film is subsequently formed, is then carried out. As a result of this wet treatment, the second sacrificial film 13 and the first sacrificial film 9 which are exposed within the cylinder holes 20 are etched in the Y-direction and the cylinder holes 20 are widened.

FIG. 1F which was mentioned above will be referred to now. The cylinder holes 20 are formed by an upper hole 20A positioned between the first insulating film 10a and the second insulating film 14a, the upper capacitor 21A being formed therein, and a lower hole 20B positioned below the first insulating film 10a, the lower capacitor 21B being formed therein. The upper hole 20A contains the uppermost-layer hole which is formed in the second insulating film 14a. Furthermore, the lower hole 20B contains the bottom-most-layer hole which is formed in the stopper silicon nitride film 8. The uppermost-layer hole is formed in the second insulating film 14a comprising a silicon nitride film and has a diameter L0. The upper hole 20A is formed in the second sacrificial film 13 comprising an undoped silicon dioxide film and has a diameter L1. Furthermore, the lower hole 20B is formed in the first sacrificial film 9 comprising a BPSG film, and has a diameter L2 at a position in proximity to the first insulating film 10a and a diameter L3 at a position in proximity to the stopper silicon nitride film 8. The bottom-most-layer hole has a diameter L4.

At the stage before the abovementioned wet treatment is carried out, the size relationship is such that L0=L1>L2>L3>L4. When the wet treatment is carried out, the increase in width of the lower hole 20B is relatively larger because the BPSG film has a faster etching rate than the undoped silicon dioxide film, as mentioned above. Furthermore, the silicon nitride film is not etched. As a result, the size relationship of the diameters at each position becomes such that L2>L1>L0>L3>L4, the diameter L2 at a position in proximity to the first insulating film 10a in the lower hole 20B where the lower capacitor 21B is formed being the largest. At the stage when the cylinder holes 20 have been formed, L0 and L1 are 50 nm, but at the stage when the wet treatment has been performed, the values change such that L1 is 55 nm, L2 is 60 nm and L3 is 40 nm. The uppermost-layer hole and the bottom-most-layer hole are formed by silicon nitride films, so there is no increase in width and L0 is unchanged at 50 nm and L4 is unchanged at 35 nm. In this mode of embodiment, the diameters of the cylinder holes 20 have a size relationship such that that L2>L1>L0>L3>L4, so it is possible to increase the surface area of the lower electrodes and thereby increase the capacitance of the capacitor.

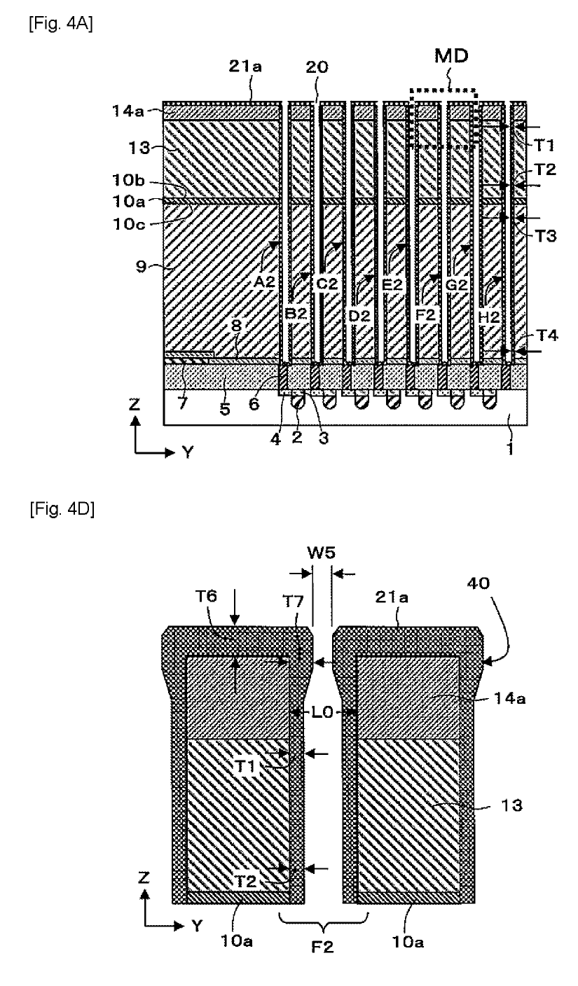

Next, as shown in FIG. 4A, a lower electrode material film formation step is carried out. That is to say, a lower electrode material film 21a is formed over the whole surface of the semiconductor substrate 1 including the inner surface of the cylinder holes 20. Titanium nitride (TiN) may be used as the material of the lower electrode material film 21a. Furthermore, CVD or ALD (Atomic Layer Deposition) or the like may be used in order to form the lower electrode material film 21a. The lower electrode material film 21a which is formed inside the cylinder holes 20 has a film thickness T1 at a position in proximity to the second insulating film 14a, a film thickness T2 at a position in proximity to the upper surface 10b of the first insulating film 10a, a film thickness T3 at a position in proximity to the lower surface of the first insulating film 10a, and a film thickness T4 at a position in proximity to the stopper silicon nitride film 8. The film thickness relationship is such that T1>T2>T3≧T4. For example, the film thickness make-up is such that if the film thickness T1 is 100%, then T2 is 85%, T3 is 82% and T4 is 81%.

However, as shown in FIG. 4D, if the lower electrode material film 21a having the film thickness required to ensure the capacitor characteristics is formed inside the cylinder holes 20 positioned below the second insulating film 14a, then an increased-width part 40 of the lower electrode material film 21a having a film thickness T7 which is approximately twice T1 is formed at the upper ends of the cylinder holes 20. This is an inevitable phenomenon due to the fact that there is a delay in the film-formation rate because the supply of film-forming gas molecules to inside the cylinder holes 20 is inadequate if the diameter of the cylinder holes 20 is narrowed, whereas there is no reduction in the film-formation rate at the upper ends where the film-forming gas molecules are sufficiently present. As a result, if the lower electrode material film 21a is formed in such a way that T1 is 10 nm, the film thickness T7 at the upper ends on the side surfaces of the second insulating film 14a is 18 nm, for example. T6 is even greater at 25 nm. In this mode of embodiment, the diameter L0 of the uppermost-layer hole is 50 nm, so the diameter W5 of the cylinder hole openings is reduced to 14 nm.

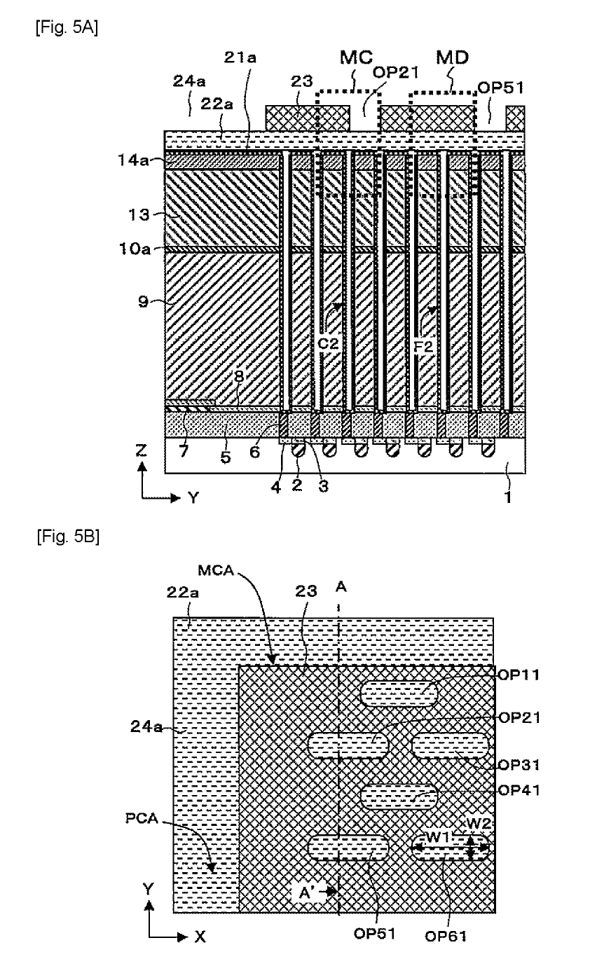

A step in which the first support film 14 is formed is carried out next, as shown in FIGS. 5A, 5B, 5C, 5D, 6A, 60, 7A, 7B and 7C.

First of all, as shown in FIG. 5A, a protective film 22a comprising a silicon dioxide film is formed over the whole surface using plasma CVD. The thickness of the protective film 22a is 100 nm, for example. The protective film 22a formed by plasma CVD has poor coverage, so it is not formed inside the cylinder holes 20, as shown in FIGS. 5C and 5D, rather it closes the upper ends thereof. The protective film 22a is formed in order to prevent a mask film comprising a photoresist from being formed inside the cylinder holes 20 in a lithography step which is subsequently carried out. This is because it is difficult to remove organic matter inside the cylinder holes having a high aspect ratio if such matter is embedded therein.

Next, a mask film 23 having a first opening pattern is formed on the protective film 22a by means of a second lithography step. As shown in FIG. 5B, a peripheral opening 24a is formed in the peripheral circuit area PCA, while a mask film 23 is formed in such a way as to cover the memory cell area MCA. Six first openings from OP11 to OP61 are formed in the mask film 23, for example. As described with reference to FIG. 1B, a single first opening has a width W1 in the X-direction and has a width W2 in the Y-direction. Furthermore, a single first opening has a pattern structure in which a first cylinder hole unit group and a second cylinder hole unit group are exposed together, the first cylinder hole unit group corresponding to a first lower electrode unit group comprising four lower electrodes adjacent in the X-direction, the second cylinder hole unit group corresponding to a second lower electrode unit group comprising four lower electrodes adjacently arranged in the Y-direction in relation to the first cylinder hole unit group. That is to say, a single first opening is formed in such a way as to lie across eight cylinder holes.

FIG. 5C is an enlargement in cross section of the region MC corresponding to the first capacitor shown in FIG. 5A. The mask film 23 is formed in such a way that the side surface of the first opening OP21 is positioned in the center in the Y-direction of the cylinder hole corresponding to the lower electrode C2. Furthermore, FIG. 5D is an enlargement in cross section of the region MD corresponding to the second capacitor shown in FIG. 5A. The first opening is not formed here so the upper surface of the protective film 22a is covered by the mask film 23.

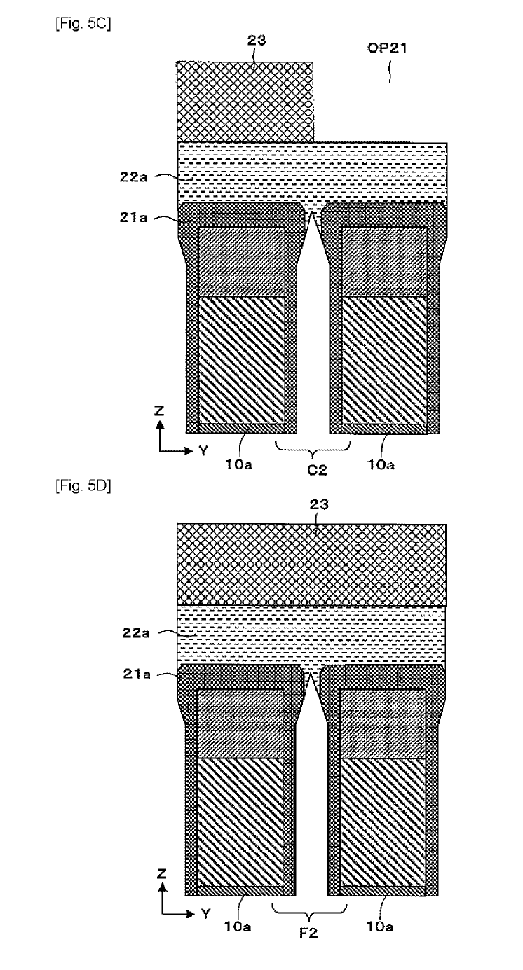

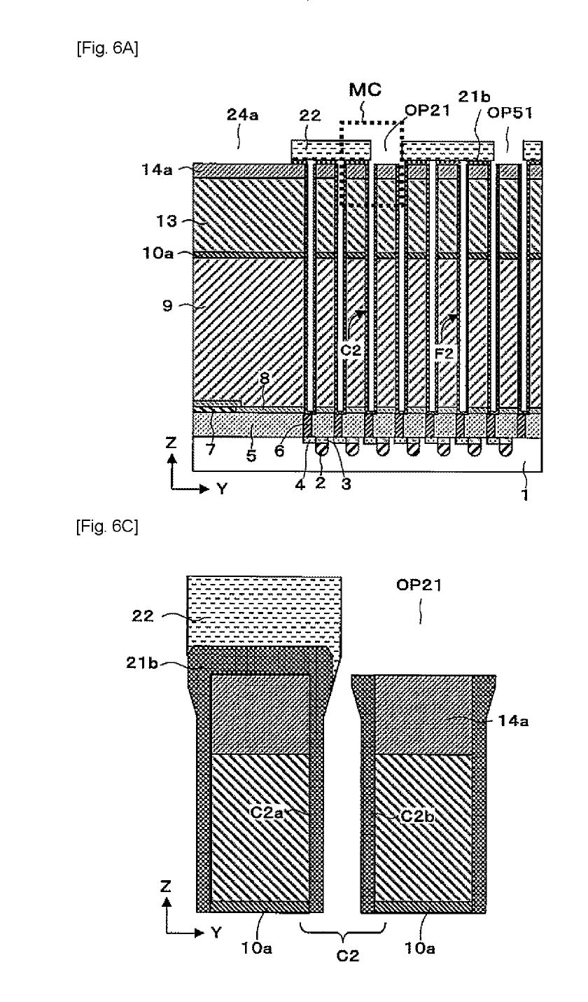

Next, as shown in FIG. 6A, the protective film 22a which is exposed inside the peripheral opening 24a and the first openings OP11-OP61 is removed by means of anisotropic dry etching employing fluorine-containing plasma and using the mask film 23 as a mask. As a result, the upper surface of the lower electrode material film 21a is exposed inside the first openings. The lower electrode material film 21a where the upper surface has been exposed is then removed by anisotropic dry etching employing chlorine-containing plasma. The mask film 23 is then removed. As a result, the protective film 22a and the lower electrode material film 21a form a new protective film 22 and a new lower electrode material film 21b to which the first opening pattern has been transferred. Furthermore, the upper surface of the second insulating film 14a is exposed within the peripheral opening 24a and the first opening OP21. Furthermore, as shown in FIG. 6C, the upper surface of the second portion C2b of the lower electrode C2 is exposed. The lower electrode material film 21b remains on the second insulating film 14a in regions outside the first openings OP11-OP61.

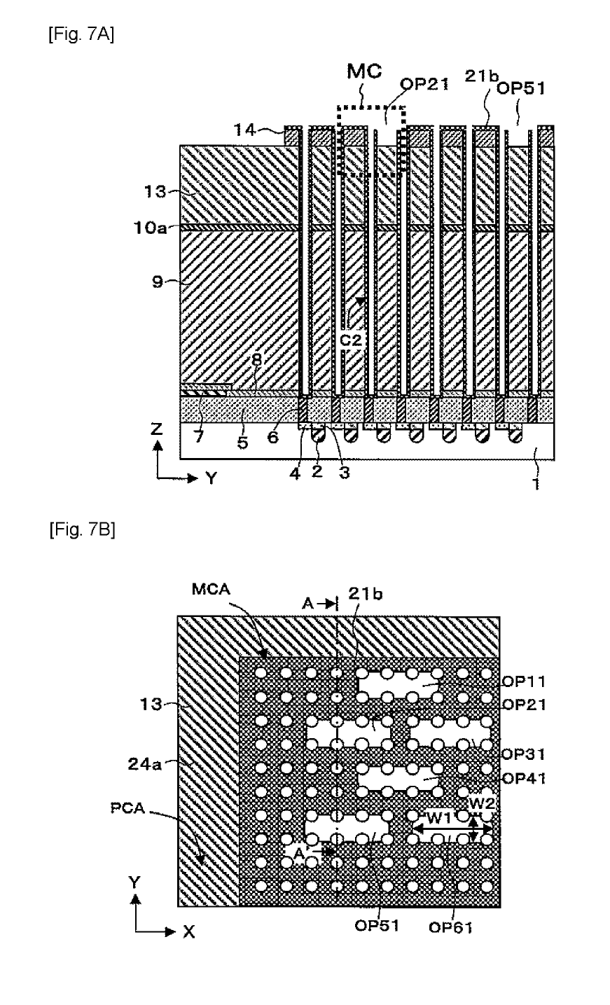

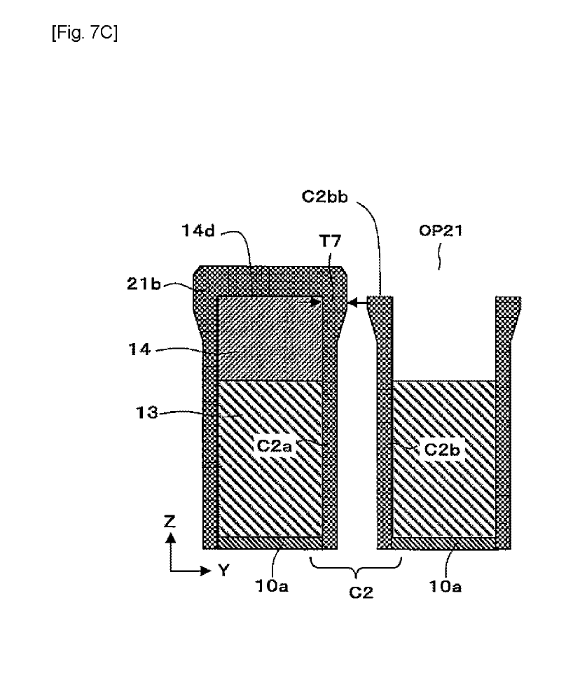

Next, as shown in FIGS. 7A, 7B and 7C, the second insulating film 14a whereof the upper surface is exposed within the peripheral opening and the first openings OP11-OP61 is removed by means of anisotropic dry etching employing fluorine-containing plasma and using the protective film 22 as a mask. The protective film 22 is also etched and destroyed by means of this etching. As a result, the first support film 14 comprising the second insulating film 14a is formed. Furthermore, the upper surface of the second sacrificial film 13 is exposed within the peripheral opening and the first openings. The second portion C2b of the lower electrode having an upper surface C2bb which is flush with an upper surface 14d of the first support film 14 is formed within the first opening.

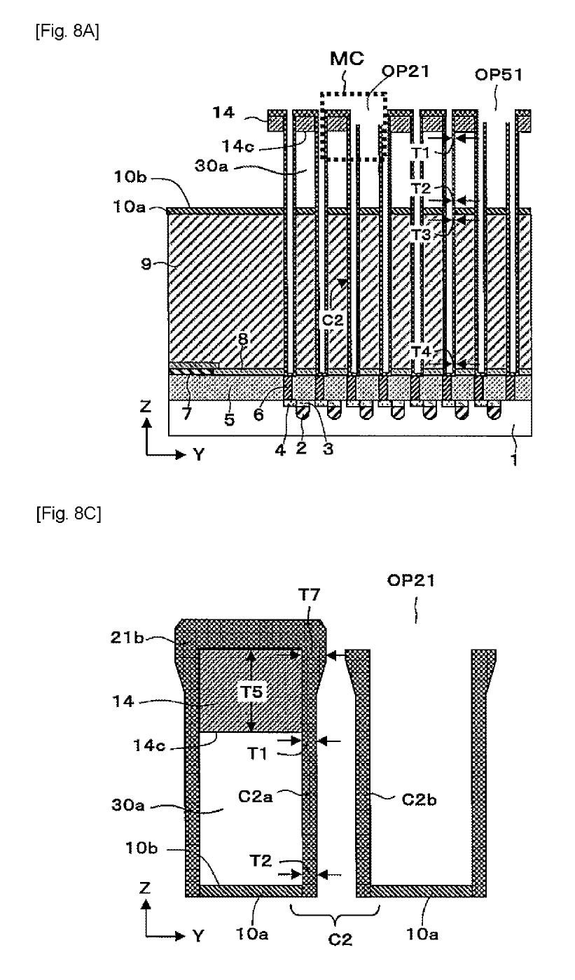

Next, as shown in FIGS. 8A and 8C, a step in which the second sacrificial film 13 is removed is carried out. The second sacrificial film 13 whereof the upper surface is exposed within the peripheral opening and the first openings is completely removed by means of a fluorine-containing solution. As is well known, solution etching is isotropic so the second sacrificial film 13 positioned below the first support film 14 is also readily removed. A lower surface 14c of the first support film 14 and the upper surface 10b of the first insulating film 10a are exposed as a result. Furthermore, a continuous first void 30a is formed at the outer circumference of all the lower electrodes below the first support film 14.

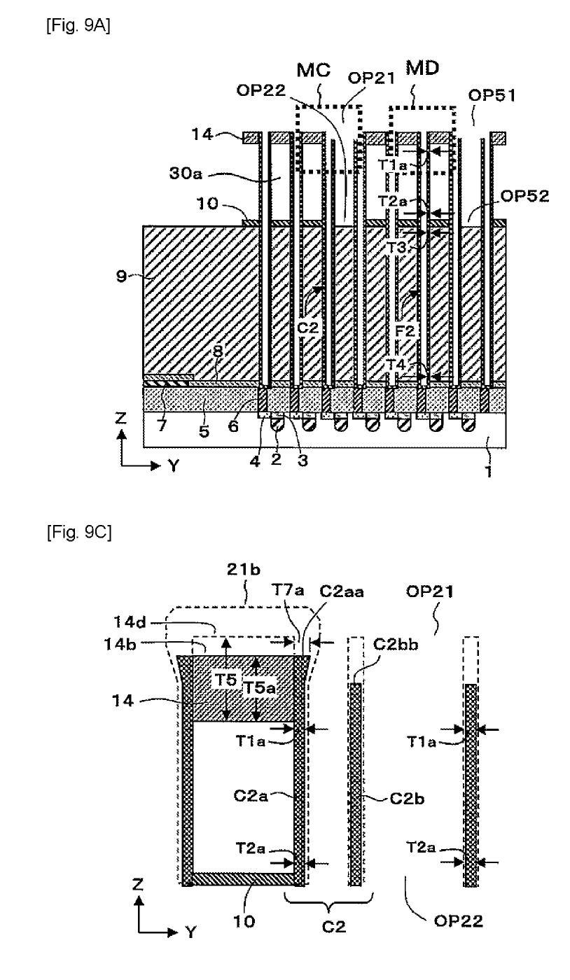

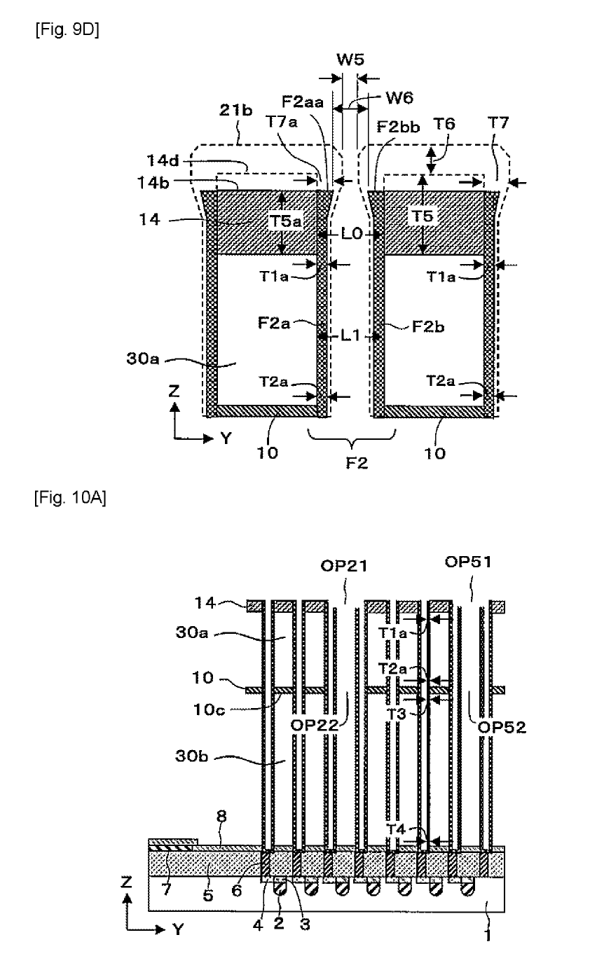

Next, as shown in FIG. 9A, a second support film formation step is carried out. The first insulating film 10a whereof the upper surface is exposed within the peripheral opening and the first openings OP21 and OP51 is removed by means of anisotropic dry etching employing mixed gas plasma containing chlorine and oxygen, and using as a mask the first support film 14 having the lower electrode material 21b formed on the upper surface thereof. As a result, second openings OP22, OP52 having the same shape and the same arrangement pattern as the first openings and aligned in the Z-direction with the first openings OP21, OP51 are formed. The second support film 10 comprising a silicon nitride film is formed by this means.

FIG. 9C will be referred to next. FIG. 9C is an enlargement in cross section of the region MC corresponding to the upper capacitor 21A in the lower electrode C2 forming part of the first capacitor. As shown in FIG. 9C, in the step of forming the second support film 10, not only the first insulating film 10a comprising a silicon nitride film but also the lower electrode material film 21b which is formed on the upper surface 14d of the first support film 14 are etched at the same time. As a result, the upper surface 14d of the first support film 14 is exposed and a first portion C2a of the lower electrode touching the side surface of the first support film 14 is formed. The upper surface 14d of the first support film 14 comprising a silicon nitride film and the upper surface of the first portion C2a are further etched, whereby a new upper surface 14b is formed on the first support film 14 and a new first upper surface C2aa is formed on the first portion C2a. The thickness of the first support film 14 is reduced from T5 to T5a. Meanwhile, the upper surface of the second portion C2b of the lower electrode which is exposed within the first opening OP21 is also etched to form a new second upper surface C2bb. The first upper surface C2aa is flush with the upper surface 14b of the first support film 14, while the second upper surface C2bb is formed at a position lower than the upper surface 14b of the first support film 14.

In this mode of embodiment, the independent lower electrodes are simultaneously formed within the respective cylinder holes 20 in the step of forming the second support film 10.

Furthermore, oxygen is contained in the plasma used for this etching, so it is possible to oxidize and remove the surface portion of the lower electrodes comprising titanium nitride. The silicon nitride film and silicon dioxide film are not oxidized, so only the surface portion of the lower electrodes comprising titanium nitride can be selectively oxidized and removed. Titanium nitride is not oxidized only by oxygen ions contained in the plasma atmosphere, but also by neutral radicals having no charge. The whole surface of the lower electrodes positioned below the first support film 14 is therefore oxidized in regions outside the first opening OP21, and not only within the first opening OP21. The removal is carried out at the same time as the following first sacrificial film removal step. By removing the oxidized titanium nitride, the lower electrodes are degraded and the width thereof is reduced. As a result, the width of the increased-width part of the first portion C2a of the lower electrodes positioned at the upper end on the side surfaces of the first support film 14 can be reduced from T7 to T7a.

Furthermore, the first portion C2a positioned below the first support film 14 is also degraded so T1 is reduced to T1a, and T2 is reduced to T2a. For example, the first support film 14 is reduced from a film thickness T5 of 130 nm to a film thickness T5a of 100 nm. The increased-width part of the first portion C2a positioned at the upper ends on the side surfaces of the first support film 14 is reduced from a width T7 of 18 nm to a width T7a of 12 nm. Furthermore, the first portion C2a and the second portion C2b of the lower electrode C2 change from a width T1 of 10 nm to a width T1a of 7 nm, and from a width T2 of 9 nm to a width T2a of 6 nm.

FIG. 9D will be referred to next. FIG. 9D is an enlargement in cross section of the region MC corresponding to the upper capacitor 21A in the lower electrode F2 forming part of the second capacitor. The basic structure is the same as that in FIG. 9C so a duplicate description will be omitted. The lower electrode F2 is not exposed within the first openings in the second capacitor, so the upper ends of the side surfaces at the outer circumference of the lower electrodes are connected to the first support film 14 around the whole circumference. This means that an upper surface F2aa of a first portion F2a and an upper surface F2bb of a second portion F2b forming part of one lower electrode F2 are both flush with the upper surface 14b of the first support film. As described above, the diameter L0 of the uppermost-layer hole is 50 nm and the width W5 of the openings at the upper ends of the cylinder holes when the lower electrode material film 21b as been formed is 14 nm. By performing the step of forming the second support film 10, the increased-width part of the first and second portions F2a, F2b of the lower electrode F2 positioned at the upper ends on the side surfaces of the first support film 14 are reduced from a width T7 of 18 nm to a width T7a of 12 nm. The width W6 of the openings at the upper ends of the cylinder holes is therefore increased to 26 nm. As a result, the openings at the upper ends of the cylinder holes do not become closed off even when the capacitance insulating film is formed in a subsequent step, and the upper electrode can be formed inside the cylinder holes.

Next, as shown in FIG. 10A, a first sacrificial film removal step is carried out. The first sacrificial film comprising a BPSG film is completely removed through the peripheral opening and the second openings OP22, OP52 by means of wet etching employing a fluorine-containing solution. Furthermore, in the step of removing the first sacrificial film, the abovementioned oxidized titanium nitride is also removed. As a result, the lower surface 10c of the second support film 10 and the upper surface of the stopper silicon nitride film 8 are exposed. Furthermore, a continuous second void 30b is formed at the outer circumference of all the lower electrodes below the second support film 10.

Next, as shown in FIGS. 1A, 1C and 1D, a capacitance insulating film and upper electrode formation step is carried out. A capacitance insulating film 25 is formed by means of ALD over the whole surface including the upper surface 14b and the lower surface 14c of the first support film 14, the upper surface 10b and the lower surface 10c of the second support film 10, the upper surface of the stopper silicon nitride film 8, and the inner and outer surfaces of each lower electrode 21. The capacitance insulating film 25 may be formed as a structure mainly comprising zirconium oxide. The thickness of the capacitance insulating film 25 is 7 nm so the openings at the upper ends of the cylinder holes 20 are not closed off, as shown in FIG. 1D. As described above, the width W6 of the openings at the upper ends before the capacitance insulating film 25 is formed is 26 nm, so an opening at the upper ends having a width of 12 nm is still present at the stage when the capacitance insulating film 25 has been formed. This means that the upper electrode 26 which is formed in such a way as to cover the capacitance insulating film 25 may be formed inside the cylinder holes 20 to a film thickness of at least 6 nm. As a result, it is possible to form a capacitor. It should be noted that the upper electrode 26 must be at least 5 nm in order to function as an electrode, and it is difficult to achieve a capacitor function if the film thickness is less than 5 nm.

Next, as shown in FIG. 1A, the upper electrode formed in the peripheral circuit area is removed by means of lithography and dry etching. A second interlayer insulating film 27 is then formed over the whole surface, after which the surface is planarize. A via plug 28 is then formed in the second interlayer insulating film 27 and upper-layer wiring 29 is formed, whereby it is possible to produce a DRAM.

A preferred mode of embodiment of the present invention has been described above but the present invention is not limited to the abovementioned mode of embodiment and various modifications are feasible within a scope that does not depart from the main point of the present invention, and it goes without saying that any such modifications are included in the scope of the present invention. For example, the Y-direction is given as the first direction and X-direction is given as the second direction, but the same effect is still achieved if the directions are switched. Furthermore, the film-formation methods and etching methods, materials and dimensions etc. are merely simple examples and these may be appropriately selected.

As described above, according to this mode of embodiment, an opening pattern is formed in such a way that two adjacent lower electrode unit groups aligned in a first direction, from among a plurality of lower electrodes arrayed in a first direction parallel to a semiconductor substrate surface and a second direction perpendicular to the first direction, are exposed together, taking four lower electrodes adjacent in the second direction as a lower electrode unit group, and therefore twisting of the lower electrodes is avoided by alleviating stress in the support film, and it is possible to prevent the problem of short-circuiting between adjacent lower electrodes.

Furthermore, the side surfaces and upper surfaces of the lower electrodes are degraded in such a way that the film thickness of the lower electrodes of the upper capacitor positioned on a second support film is at its smallest at a position in proximity to the second support film, so it is possible to form a capacitor in which the diameter of the openings in the lower electrodes can be increased and closure can be avoided.

This application claims priority to Japanese Application 2012-271555 filed on Dec. 12, 2012, the disclosure of which is hereby incorporated in its entirety.

### KEY TO SYMBOLS

1 . . . Semiconductor substrate
2 . . . Embedded gate electrode
3 . . . Cap insulating film
4 . . . Impurity diffusion layer
5 . . . First interlayer insulating film
6 . . . Contact plug
7 . . . Peripheral circuit
8 . . . Stopper silicon nitride film
9 . . . First sacrificial film
10 . . . Second support film
10a . . . First insulating film
10b . . . Upper surface of second support film (first insulating film)
10c . . . Lower surface of second support film (first insulating film)
11 . . . First mask film
12 . . . Second opening
13 . . . Second sacrificial film
14 . . . First support film
14a . . . Second insulating film
14b . . . Upper surface after etch-back of first support film (second insulating film)
14c . . . Lower surface of first support film (second insulating film
14d . . . Upper surface before etch-back of first support film (second insulation film)
15 . . . Hard mask film
15a . . . Amorphous silicon film
15b . . . Silicon dioxide film
15c . . . Amorphous carbon film
16 . . . Hard mask film
17 . . . Antireflection film
18 . . . Organic mask film
19 . . . Cylinder hole pattern
20 . . . Cylinder hole
21a, 21b . . . Lower electrode material film
21 . . . Lower electrode
21c, 21d, 21e . . . Lower electrode portion
21cc, 21dd . . . Upper surface of lower electrode
22, 22a . . . Protective film
23 . . . Mask film
24 . . . First opening
24a . . . Peripheral opening
OP11-OP61 . . . First opening
OP12-OP62 . . . Second opening
C2, F2 . . . Lower electrode
C2a, F2a . . . First portion
C2b, F2b . . . Second portion
C2aa . . . First upper surface
C2bb . . . Second upper surface
25 . . . Capacitance insulating film
26 . . . Upper electrode
27 . . . Second interlayer insulating film
28 . . . Via plug
29 . . . Upper-layer wiring
30a . . . First void
30b . . . Second void

1. A semiconductor device comprising:
a plurality of lower electrodes arranged on a semiconductor substrate in a first direction parallel to the surface of the semiconductor substrate and a second direction perpendicular to the first direction, and extending in a third direction perpendicular to the surface of the semiconductor substrate;
a first support film provided at a position corresponding to the upper end of the plurality of lower electrodes and having a plurality of first openings;
a second support film provided at a position corresponding to the middle of the plurality of lower electrodes in relation to the third direction and having a plurality of second openings;
a capacitance insulating film covering the surface of the plurality of lower electrodes; and
an upper electrode covering the surface of the capacitance insulating film, wherein the plurality of first openings and the plurality of second openings are aligned on a plane in the same pattern and are provided at overlapping positions in the third direction, and the plurality of first openings and the plurality of second openings are constructed in such a way that a portion of each of eight lower electrodes included in two lower electrode unit groups adjacent in the first direction are positioned together inside the respective first openings and second openings, and wherein four lower electrodes adjacent in the second direction from among the plurality of lower electrodes constitute a lower electrode unit group.

2. The semiconductor device of claim 1, wherein the plurality of lower electrodes are arranged at an equal arrangement pitch in relation to the first direction and the second direction, and the plurality of first openings are formed by a rectangular shape comprising a long side which has a length equal to three times the length of the arrangement pitch and extends in the second direction, and a short side which has a length equal to the arrangement pitch and extends in the first direction.

3. The semiconductor device of claim 1, wherein the two lower electrodes positioned at both ends from among the four lower electrodes included in a lower electrode unit group have an overlap in plan view with the first opening at the corners of the corresponding first opening, and the two lower electrodes in the center have an overlap in plan view with the first opening on the long sides of the corresponding first opening.

4. The semiconductor device of claim 1, wherein the plurality of first openings are arranged across the eight lower electrodes in such a way as to overlap the upper surfaces of the four lower electrodes at the corners and to overlap the upper surfaces of the four electrodes on the long sides.

5. The semiconductor device of claim 2, wherein the plurality of first openings adjacent in the second direction are disposed in a straight line and the interval between two adjacent first openings is equal to the abovementioned arrangement pitch.

6. The semiconductor device of claim 2, wherein the plurality of first openings are staggered in such a way that the interval between two or more first openings arranged in the first direction is equal to the abovementioned arrangement pitch, and the first openings adjacent in the second direction are arranged at positions offset from each other in the first direction by a distance equal to twice the abovementioned arrangement pitch.

7. The semiconductor device of claim 1, wherein the center line of the plurality of first openings in the second direction does not intersect another nearest-neighbor first opening adjacent in the first direction.

8. The semiconductor device of claim 1, wherein the plurality of first openings are arranged in such a way that rows of multiple openings formed by arranging two or more first openings in the second direction have an interval between them in the first direction, and the rows of openings include first openings arranged on a straight line in the first direction which are alternately disposed in the first direction.

9. The semiconductor device of claim 1, wherein said semiconductor device has a memory cell area and a peripheral circuit area, and the first support film and the second support film are connected to all of the plurality of lower electrodes positioned within the memory cell area and are constructed in a continuous planar form.

10. A semiconductor device comprising:
a plurality of lower electrodes extending in a third direction perpendicular to a semiconductor substrate surface;
a first support film disposed at a position corresponding to the upper ends of the plurality of lower electrodes and having a rectangular first opening;
a second support film disposed at a position corresponding to the middle of the plurality of lower electrodes in the third direction and having a rectangular second opening;
a capacitance insulating film covering the surface of the plurality of lower electrodes; and
an upper electrode covering the surface of the capacitance insulating film, the plurality of lower electrodes, wherein the capacitance insulating film and the upper electrode form a capacitor group, and the capacitor group comprises:
a first capacitor which is arranged on the sides of the first openings in plan view with part of the outer circumferential side surface of the lower electrodes being connected to the first support film; and
a second capacitor in which the whole of the outer circumferential side surface of the lower electrodes is connected to the first support film without being exposed within the first opening, wherein the upper surfaces of the lower electrodes forming part of the first capacitor include a first upper surface which is flush with the upper surface of the first support film, and a second upper surface which is at a lower level than the upper surface of the first support film.

11. The semiconductor device of claim 10, wherein the plurality of lower electrodes have a ring-shaped upper surface in plan view, and the first upper surface is a partial upper surface of the lower electrodes positioned outside the first openings, and the second upper surface is another partial upper surface of the lower electrodes positioned within the first openings.

12. A semiconductor device comprising:
lower electrodes connected to the upper surface of a contact plug disposed on a semiconductor substrate and extending in a third direction perpendicular to the semiconductor substrate surface;
a first support film connected to the outer circumference at the upper end of the lower electrodes;
a second support film connected to the outer circumference of the middle section of the lower electrodes in the third direction;
a capacitance insulating film covering the surface of the lower electrodes; and
an upper electrode covering the surface of the capacitance insulating film, the lower electrodes, wherein the capacitance insulating film and upper electrode form a capacitor, the capacitor includes a lower capacitor which is positioned between the upper surface of the contact plug and the second support film, and an upper capacitor which is positioned between the lower surface of the second support film and the upper surface of the first support film, and if T1a is the film thickness of the lower electrodes of the upper capacitor at a position in proximity to the first support film, T2a is the film thickness of the lower electrodes of the upper capacitor at a position in proximity to the second support film, T3 is the film thickness of the lower electrodes of the lower capacitor at a position in proximity to the second support film, and T4 is the film thickness of the lower electrodes of the lower capacitor at a position in proximity to the contact plug, then T2a is the smallest.

13. The semiconductor device of claim 12, comprising a stopper silicon nitride film surrounding the bottom part of the lower capacitor, and if L0 is the outer diameter of the lower electrodes of the upper capacitor at a position corresponding to the first support film, L1 is the outer diameter of the lower electrodes of the upper capacitor between the first support film and the second support film, L2 is the outer diameter of the lower electrodes of the lower capacitor at a position in proximity to the second support film, and L3 is the outer diameter of the lower electrodes of the lower capacitor at a position in proximity to the stopper silicon nitride film, then L2 is the greatest.

14. A method for producing a semiconductor device, comprising:
forming a stopper silicon nitride film, a first sacrificial film, a first insulating film, a second sacrificial film, and a second insulating film in succession on a semiconductor substrate;
forming a cylinder hole through the second insulating film, second sacrificial film, first insulating film, first sacrificial film, and stopper silicon nitride film;
widening the cylinder hole;
a step in which a lower electrode material film is formed over the whole surface of the cylinder hole including the inner surface;
forming a protective film on the upper surface of the lower electrode material film;
forming a first opening pattern, which at least partially maintains the connection between the lower electrode material film and the surface of the second insulating film forming part of the inner surface of the cylinder hole, on the protective film;
forming a first support film by forming a first opening in the second insulating film using the protective film as a mask;
removing the second sacrificial film through the first opening;
forming a second opening comprising the same pattern as the first opening in the first insulating film by means of anisotropic dry etching using the first support film as a mask in order to form a second support film, and removing the lower electrode material film formed on the upper surface of the first support film to form lower electrodes in which the outer circumferential side surface is connected to the second support film and the first support film within the cylinder hole; and
removing the whole of the first sacrificial film through the second opening, wherein forming the second opening comprise excavating the upper surface of the first support film and the upper surface of the lower electrodes while at the same time degrading the upper side surface of the lower electrodes.

15. The method of claim 14, wherein widening the cylinder hole comprises widening such that, if L1 is the diameter of the cylinder hole between the first support film and the second support film, L2 is the diameter of the cylinder hole between the second support film and the stopper silicon nitride film at a position in proximity to the second support film, and L3 is the diameter of the cylinder hole at a position in proximity to the stopper silicon nitride film, then L2 is the greatest.

16. The method of claim 14, wherein degrading the upper side surface of the lower electrodes comprises degrading formed is degraded in such a way that, if T1a is the film thickness of the lower electrodes at a position in proximity to the first support film between the first support film and the second support film, T2a is the film thickness of the lower electrodes at a position in proximity to the second support film between the first support film and the second support film, T3 is the film thickness of the lower electrodes at a position in proximity to the second support film between the second support film and the stopper silicon nitride film, and T4 is the film thickness of the lower electrodes at a position in proximity to the stopper silicon nitride film, then T2a is the smallest.

17. The method of claim 14, wherein the second opening has the same shape and the same layout as the first opening pattern, and is formed at an overlapping position aligned in a third direction perpendicular to the semiconductor substrate surface.

18. The method of claim 14, wherein forming the cylinder hole comprises forming a plurality of cylinder holes in an arrangement in a first direction parallel to the surface of the semiconductor substrate and a second direction perpendicular to the first direction, and forming a plurality of lower electrodes correspondingly with the plurality of cylinder holes.

19. The method of claim 18, wherein the first opening pattern is formed in such a way that a portion of each of eight lower electrodes included in two lower electrode unit groups adjacent in the first direction are positioned together inside the first opening, and wherein four lower electrodes adjacent in the second direction in a plan view constitute a lower electrode unit group.

20. The method of claim 18, wherein the lower electrodes are formed in such a way that the upper surface thereof has a ring shape in plan view.

21. The method of claim 18, wherein the plurality of cylinder holes are formed at an equal arrangement pitch in relation to the first direction and the second direction, and the first opening is formed as a rectangular shape comprising a long side which has a length that is three times the length of the arrangement pitch and extends in the second direction, and a short side which has a length equal to the arrangement pitch and extends in the first direction.

22. The method of claim 19, wherein two of the lower electrodes positioned at both ends from among the four lower electrodes included in the lower electrode unit group are formed in such a way as to overlap the first opening at the corners of the first opening in plan view, and the two lower electrodes positioned in the center are formed in such a way as to overlap the first opening on the long side of the first opening in plan view.

23. The method of claim 18, wherein the first openings are formed across eight lower electrodes in such a way as to overlap the upper surfaces of four lower electrodes at the corners, and to overlap the upper surfaces of four lower electrodes on the long sides.

24. The method of claim 18, wherein the first openings are formed in such a way that a plurality of first openings are disposed in a straight line at intervals equal to the abovementioned arrangement pitch in relation to the second direction.

25. The method of claim 18, wherein the first openings are formed in such a way that a plurality of first openings are staggered, so that two or more first openings are disposed at an interval equal to the abovementioned arrangement pitch in relation to the first direction, and first openings adjacent in the second direction are arranged at positions offset from each other in the first direction by a distance equal to twice the abovementioned arrangement pitch.

26. The method of claim 18, wherein the first openings are formed in such a way that the center line of the plurality of first openings in the second direction does not intersect another nearest-neighbor first opening adjacent in the first direction.

27. The method of claim 18, wherein the first openings are formed in such a way that rows of multiple openings formed by arranging a plurality of first openings in the second direction have an interval between them in the first direction, and the rows of openings include first openings arranged on a straight line in the first direction which are alternately disposed in the first direction.

28. The method of claim 14, wherein the first support film and the second support film are formed in such a way as to be connected to all of the lower electrodes positioned within one memory cell area.
